(19) United States
(12) Patent Application Publication
(10) Pub. No.: US 2017/0365209 A1
(43) Pub. Date: Dec. 21, 2017

(54) SEMICONDUCTOR DEVICE, DISPLAY DEVICE, AND ELECTRONIC DEVICE

(71) Applicant: Semiconductor Energy Laboratory Co., Ltd., Atsugi-shi (JP)

(72) Inventor: Yoshiyuki KUROKAWA, Sagamihara (JP)

(21) Appl. No.: 15/622,311

(22) Filed: Jun. 14, 2017

(30) Foreign Application Priority Data
Jun. 17, 2016 (JP) 2016-120435

(51) Int. Cl. G09G 3/20; G02F 1/1335; G02F 1/1368; G09G 3/3225; G09G 3/36; H01L 27/12; H01L 27/32; G09G 3/3275; G06F 3/041; H01L 29/786; G02F 1/1333

(52) U.S. Cl. CPC G09G 3/2096; H01L 27/3262; G02F 1/133555; G02F 1/1368; G09G 3/3225; G09G 3/3275; G09G 3/3648; G09G 3/3688; H01L 27/1225; H01L 27/1251; H01L 27/3232; G09G 2310/08; G09G 2330/021; G09G 2360/12; G02F 2201/44; H01L 29/7869; H01L 27/323; G09G 2300/0852; G02F 1/13338; G06F 3/0416

(57) ABSTRACT

A semiconductor device with low power consumption is provided. The semiconductor device includes a controller, a register, and an image processing portion. The image processing portion is configured to process an image data using a parameter. The image processing portion receives an image data from a frame memory and receives a parameter from the register. The frame memory is configured to retain the image data while power supply is stopped. The register is configured to retain the parameter while the power supply is stopped. The controller is configured to control power supply to the register, power supply to the frame memory, and power supply to the image processing portion. The register includes a scan chain register. A transistor with which the scan chain register is configured includes an oxide semiconductor in a channel formation region.

### BACKGROUND OF THE INVENTION

### 1. Field of the Invention

One embodiment of the present invention relates to a semiconductor device.

Note that one embodiment of the present invention is not limited to the above technical field. The technical field of the invention disclosed in this specification and the like relates to an object, a method, or a manufacturing method. Furthermore, one embodiment of the present invention relates to a process, a machine, manufacture, or a composition of matter.

Specifically, examples of the technical field of one embodiment of the present invention disclosed in this specification and the like include a semiconductor device, a display device, an electronic device, a method for driving any of them, and a method for manufacturing any of them. In this specification and the like, a semiconductor device generally means a device that can function by utilizing semiconductor characteristics.

### 2. Description of the Related Art

A display device in which a reflection-type element and a light emission type element are combined has been proposed (Patent Document 1). The reflection-type element is used in bright environments and the light emission type element is used in dark environments, so that it is possible to achieve high display quality independent of environment light and to provide a low power consumption display device.

A technique for using an oxide semiconductor transistor (hereinafter referred to as an OS transistor) for a display device such as a liquid crystal display or an organic electroluminescent (EL) display has been proposed. The refresh frequency at the time of displaying still images is reduced because an OS transistor has an extremely low off-state current, resulting in reduction in power consumption of liquid crystal displays or organic EL displays. Such a technique has been disclosed (Patent Document 2 and Patent Document 3). Note that the above-described technique for reducing the power consumption of the display device is referred to as idling stop or IDS driving in this specification.

An example in which an OS transistor, which has an extremely low off-state current, is used in a nonvolatile memory device has been disclosed (Patent Document 4).

### REFERENCES

### Patent Documents

### [Patent Document 1]

Japanese Published Patent Application No. 2003-157026

### [Patent Document 2]

Japanese Published Patent Application No. 2011-141522

### [Patent Document 3]

Japanese Published Patent Application No. 2011-141524

### [Patent Document 4]

Japanese Published Patent Application No. 2011-151383

### SUMMARY OF THE INVENTION

To perform display using the reflection type element in bright environments and the light emission type element in dark environments, a semiconductor device which distributes image data to each display element by detecting external light is necessary. The semiconductor device does not need to transmit image data or a signal to a display device while the display device performs IDS driving; thus, power supply for related circuits to the transmission can be stopped. An object of one embodiment of the present invention is to provide a semiconductor device which has low power consumption and a mechanism in which display quality is not influenced even when power supply for some circuits is stopped.

Another object of one embodiment of the present invention is to provide a novel semiconductor device. Another object of one embodiment of the present invention is to provide a semiconductor device with low power consumption. Another object of one embodiment of the present invention is to provide a display device including the novel semiconductor device. Another object of one embodiment of the present invention is to provide an electronic device using the display device including the novel semiconductor device.

One embodiment of the present invention does not necessarily achieve all the objects listed above and only needs to achieve at least one of the objects. The description of the above objects does not preclude the existence of other objects. Other objects will be apparent from and can be derived from the description of the specification, the claims, the drawings, and the like.

One embodiment of the present invention is a semiconductor device including a first controller, a register, a frame memory, and an image processing portion. The frame memory is configured to store image data. The image processing portion is configured to process the image data. The register is configured to store a parameter for performing processing in the image processing portion. The frame memory is configured to retain the image data while power supply to the frame memory is stopped. The register includes a scan chain register, a first register, and a second register; the scan chain register is configured to retain the parameter while power supply to the register is stopped; a transistor with which the scan chain register is configured includes an oxide semiconductor in a channel formation region. The first controller is configured to control power supply to the register, power supply to the frame memory, and power supply to the image processing portion.

One embodiment of the present invention is the semiconductor device according to the above embodiment in which the scan chain register includes a third register and a fourth register. An output terminal of the third register is electrically connected to an input terminal of the fourth register. The first register is configured to read data stored in the third register. The second register is configured to read data stored in the fourth register. The data read by the first register and the second register are output to the image processing portion as the parameter.

One embodiment of the present invention is the semiconductor device according to the above embodiment in which the first register includes a first input terminal, a first output terminal, and a second output terminal, in which the second register includes a second input terminal, a third output terminal, and a fourth output terminal, in which the third register includes a third input terminal, a fourth input terminal, and a fifth output terminal, and in which the fourth register includes a fifth input terminal, a sixth input terminal, and a sixth output terminal. The first output terminal of the first register is electrically connected to the image processing portion. The third output terminal of the second register is electrically connected to the image processing portion. The first input terminal of the first register is electrically connected to the fifth output terminal of the third register. The second output terminal of the first register is electrically connected to the fourth input terminal of the third register. The second input terminal of the second register is electrically connected to the sixth output terminal of the fourth register. The fourth output terminal of the second register is electrically connected to the sixth input terminal of the fourth register. The fifth output terminal of the third register is electrically connected to the fifth input terminal of the fourth register. The first register is configured to store data input to the first input terminal. The second register is configured to store data input to the second input terminal.

One embodiment of the present invention can provide a novel semiconductor device. One embodiment of the present invention can provide a novel semiconductor device with low power consumption.

One embodiment of the present invention can provide a display device including the novel semiconductor device. One embodiment of the present invention can provide an electronic device using the display device including the novel semiconductor device.

Note that the effects of one embodiment of the present invention are not limited to the above effects. The effects described above do not preclude the existence of other effects. The other effects are the ones that are not described above and will be described below. The other effects will be apparent from and can be derived from the description of the specification, the drawings, and the like by those skilled in the art. One embodiment of the present invention has at least one of the above effects and the other effects. Accordingly, one embodiment of the present invention does not have the above effects in some cases.

### BRIEF DESCRIPTION OF THE DRAWINGS

In the accompanying drawings:

FIG. 1 is a block diagram illustrating a configuration example of a display device;

FIG. 2 illustrates a configuration example of a touch sensor unit;

FIG. 3 is a block diagram illustrating a configuration example of a controller IC;

FIGS. 4A to 4C each show a parameter;

FIGS. 5A and 5B are block diagrams illustrating a configuration example of a frame memory;

FIG. 6 is a block diagram illustrating a configuration example of a register;

FIG. 7 is a circuit diagram illustrating a configuration example of the register;

FIG. 8 is a timing chart illustrating an operation example of the register;

FIG. 9 is a block diagram illustrating a configuration example of the controller IC;

FIG. 10 is a block diagram illustrating a configuration example of a display unit;

FIG. 11 is a circuit diagram illustrating a configuration example of pixels;

FIGS. 12A to 12C are top views illustrating a structure example of the display unit and a configuration example of the pixel;

FIGS. 13A and 13B are cross-sectional views illustrating a structure example of the display unit;

FIGS. 14A and 14B are cross-sectional views illustrating a structure example of the display unit;

FIGS. 15A to 15C are schematic views illustrating shapes of reflective films;

FIGS. 16A and 16B are bottom views each illustrating part of a pixel of a display unit;

FIG. 17 is a block diagram showing a configuration example of a display device;

FIG. 18A is a top view illustrating the display device, and FIG. 18B is a schematic view illustrating part of an input portion of the display device;

FIGS. 19A and 19B are cross-sectional views illustrating a structure example of a display device;

FIG. 20 is a cross-sectional view illustrating a structure example of the display device;

FIGS. 21A to 21H are perspective views each illustrating examples of an electronic device.

### DETAILED DESCRIPTION OF THE INVENTION

Hereinafter, embodiments will be described with reference to drawings. However, the embodiments can be implemented with various modes. It will be readily appreciated by those skilled in the art that modes and details can be changed in various ways without departing from the spirit and scope of the present invention. Thus, the present invention should not be interpreted as being limited to the following description of the embodiments. Any of the embodiments described below can be combined as appropriate.

Note that a controller IC described in embodiments is a semiconductor device including a transistor including silicon in a channel formation region, a transistor including an oxide semiconductor in a channel formation region, a capacitor, and the like. Thus, a controller IC can be referred to as a semiconductor device.

In this specification and the like, an oxide semiconductor is referred to as an OS in some cases. Thus, a transistor including an oxide semiconductor in a channel formation region is referred to as an oxide semiconductor transistor, an OS transistor, or an OSFET in some cases.

In the drawings and the like, the size, the layer thickness, the region, or the like is exaggerated for clarity in some cases. Therefore, the size, the layer thickness, or the region is not limited to the illustrated scale. Note that the drawings are schematic views showing ideal examples, and embodiments of the present invention are not limited to the shapes or values shown in the drawings.

The same elements or elements having similar functions, elements formed using the same material, elements formed at the same time, or the like in the drawings and the like are denoted by the same reference numerals, and the description thereof is not repeated in some cases.

In this specification and the like, the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

In this specification and the like, the term for describing arrangement, such as “over” or “below” does not necessarily mean that a component is placed “directly over” or “directly below” another component. For example, the expression “a gate electrode over a gate insulating layer” can mean the case where there is an additional component between the gate insulating layer and the gate electrode.

In this specification and the like, the term “parallel” indicates that the angle formed between two straight lines is greater than or equal to −10° and less than or equal to 10°, and accordingly also includes the case where the angle is greater than or equal to −5° and less than or equal to 5°. The term “perpendicular” indicates that the angle formed between two straight lines is greater than or equal to 80° and less than or equal to 100°, and accordingly also includes the case where the angle is greater than or equal to 85° and less than or equal to 95°.

In this specification and the like, ordinal numbers such as “first”, “second”, and “third” are used in order to avoid confusion among components, and do not limit the number of components.

In this specification and the like, the term “electrically connected” includes the case where components are connected through an object having any electric function. There is no particular limitation on the “object having any electric function” as long as electric signals can be transmitted and received between components that are connected through the object. Examples of an “object having any electric function” are a switching element such as a transistor, a resistor, an inductor, a capacitor, and an element with a variety of functions as well as an electrode and a wiring.

In this specification and the like, “voltage” refers to a difference between a given potential and a reference potential (e.g., a ground potential) in many cases. Accordingly, voltage, potential, and potential difference can also be referred to as potential, voltage, and voltage difference, respectively.

In this specification and the like, a transistor is an element having at least three terminals of a gate, a drain, and a source. The transistor has a channel region between a drain (a drain terminal, a drain region, or a drain electrode) and a source (a source terminal, a source region, or a source electrode), and current can flow between the drain and the source through the channel region. Note that in this specification and the like, a channel region refers to a region through which current mainly flows.

Furthermore, functions of a source and a drain might be switched when transistors having different polarities are employed or a direction of current flow is changed in circuit operation, for example. Therefore, the terms “source” and “drain” can be switched in this specification and the like.

Unless otherwise specified, off-state current in this specification and the like refers to drain current of a transistor in an off state (also referred to as a non-conducting state and a cutoff state). Unless otherwise specified, the off state of an n-channel transistor means that the voltage between its gate and source (Vgs: gate-source voltage) is lower than the threshold voltage Vth, and the off state of a p-channel transistor means that the gate-source voltage Vgs is higher than the threshold voltage Vth. That is, the off-state current of an n-channel transistor sometimes refers to drain current that flows when the gate-source voltage Vgs is lower than the threshold voltage Vth.

In the above description of off-state current, a drain may be replaced with a source. That is, the off-state current sometimes refers to current that flows through a source when a transistor is off

In this specification and the like, the term “leakage current” sometimes expresses the same meaning as “off-state current”. In addition, in this specification and the like, the off-state current sometimes refers to current that flows between a source and a drain when a transistor is off, for example.

### Embodiment 1

In this embodiment, a hybrid display device in which a reflection type element and a light emission type element are provided in one pixel will be described. In particular, a controller IC of the display device will be described. Note that liquid crystal, electronic paper, or the like can be used as the reflection type element. The reflection type element and the light emission type element will be described below as a reflective element 10a and a light-emitting element 10b, respectively.

### <<Display Device>>

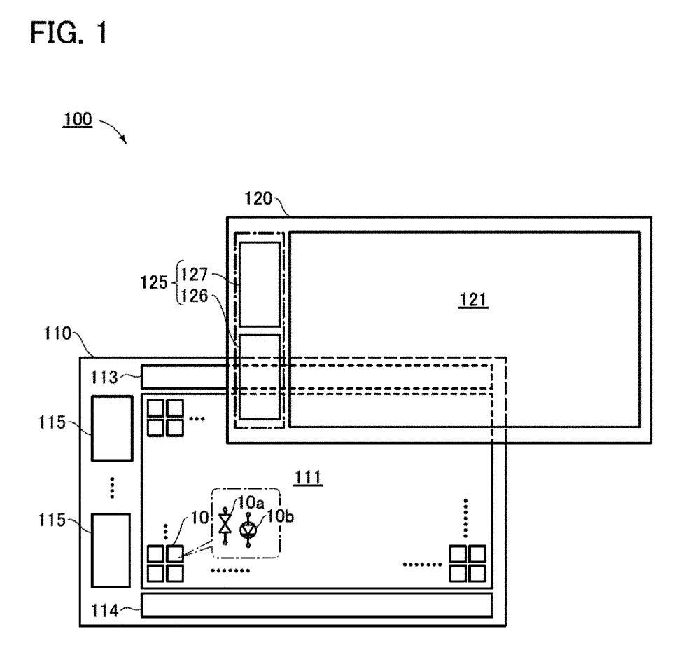

FIG. 1 is a block diagram illustrating a structure example of a display device. A display device 100 includes a display unit 110 and a touch sensor unit 120.

### <Display Unit>

The display unit 110 includes a pixel array 111, a gate driver 113, a gate driver 114, and controller ICs 115.

The pixel array 111 includes a plurality of pixels 10, and each pixel 10 is an active element driven by a transistor. The pixel 10 includes the reflective element 10a and the light-emitting element 10b. A more specific structure example of the pixel array 111 will be described in Embodiment 2.

The gate driver 113 is configured to drive a gate line for selecting the reflective element 10a, and the gate driver 114 is configured to drive a gate line for selecting the light-emitting element 10b. The controller IC 115 is provided with a source driver for driving a source line that supplies a data signal to the reflective element 10a and a source driver for driving a source line that supplies a data signal to the light-emitting element 10b. The controller IC 115 is configured to collectively control the operation of the display device 100. The number of controller ICs 115 is determined in accordance with the number of pixels of the pixel array 111.

Although FIG. 1 illustrates an example in which the gate driver 113 and the gate driver 114 are integrated together with the pixel array 111 over the same substrate, the gate driver 113 and the gate driver 114 can be dedicated ICs. Alternatively, the gate driver 113 or the gate driver 114 may be incorporated in the controller ICs 115.

Although the controller IC 115 is mounted by a chip on glass (COG) method here, there is no particular limitation on the mounting method, and a chip on flexible (COF) method, a tape automated bonding (TAB) method, or the like may be employed. The same applies to a method for mounting an IC on the touch sensor unit 120.

Note that the transistor used for the pixel 10 is a transistor including an oxide semiconductor in a channel formation region (also referred to as an “OS transistor”), which has a lower off-state current than that of a Si transistor. The off-state current of an OS transistor can be extremely low by reducing the concentration of impurities in an oxide semiconductor to make the oxide semiconductor intrinsic or substantially intrinsic.

Alternatively, a transistor that does not include an oxide semiconductor can be used for the pixel 10 as long as the transistor has a low off-state current. For example, a transistor including a wide-bandgap semiconductor may be used. The wide-bandgap semiconductor is a semiconductor whose bandgap is 2.2 eV or greater. Examples of the wide-bandgap semiconductor materials include silicon carbide, gallium nitride, and diamond.

By using the transistor having a low off-state current for the pixel 10, the gate driver 113, the gate driver 114, and the source driver can be temporarily stopped (hereinafter the temporary stop is referred to as “idling stop” or “IDS driving”) in the case where rewriting of a display screen is not necessary, that is, a still image is displayed. Power consumption of the display device 100 can be reduced by IDS driving.

### <Touch Sensor Unit>

The touch sensor unit 120 in FIG. 1 includes a sensor array 121 and a peripheral circuit 125. The peripheral circuit 125 includes a touch sensor driver (hereinafter referred to as a “TS driver”) 126 and a sensing circuit 127. The peripheral circuit 125 can be composed of a dedicated IC.

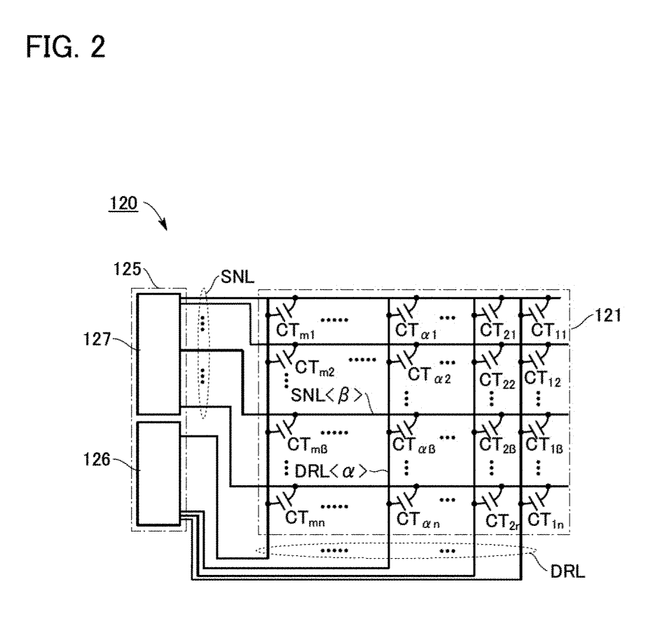

FIG. 2 illustrates a configuration example of the touch sensor unit 120. Here, the touch sensor unit 120 is a mutual capacitive touch sensor unit as an example. The sensor array 121 includes m wirings DRL and n wirings SNL, where m is an integer greater than or equal to 1 and n is an integer greater than or equal to 1. The wiring DRL is a driving line, and the wiring SNL is a sensing line. Here, the α-th wiring DRL is referred to as wiring DRL<α>, and the β-th wiring SNL is referred to as wiring SNL<β>. A capacitor CT_{αβ} refers to a capacitor formed between the wiring DRL<α> and the wiring SNL<β>.

The m wirings DRL are electrically connected to the TS driver 126. The TS driver 126 is configured to drive each wiring DRL. The n wirings SNL are electrically connected to the sensing circuit 127. The sensing circuit 127 is configured to sense signals of wirings SNL. A signal of the wiring SNL<β> at the time when the wiring DRL<α> is driven by the TS driver 126 has information on the change amount of capacitance of the capacitor CT_{αβ}. By analyzing signals of n wirings SNL, information on whether touch operation is performed or not, touch position, and the like can be obtained.

### <<Controller IC>>

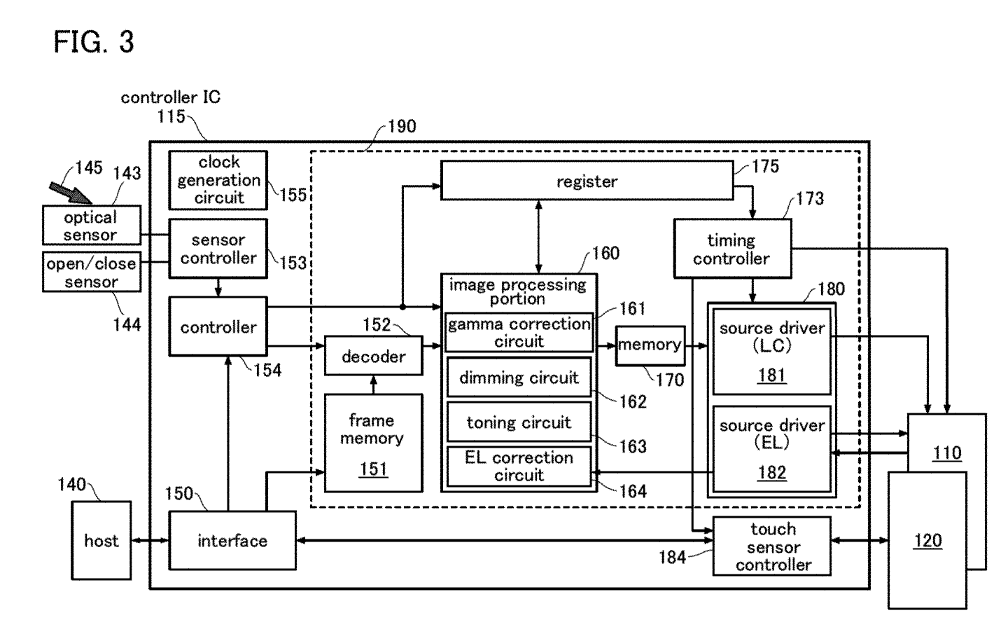

FIG. 3 is a block diagram illustrating a configuration example of the controller IC 115. The controller IC 115 includes an interface 150, a frame memory 151, a decoder 152, a sensor controller 153, a controller 154, a clock generation circuit 155, an image processing portion 160, a memory 170, a timing controller 173, a register 175, a source driver 180, and a touch sensor controller 184.

The source driver 180 includes a source driver 181 and a source driver 182. The source driver 181 is a driver for driving the reflective element 10a, and the source driver 182 is a driver for driving the light-emitting element 10b. Here, a controller IC in the case where the reflective element 10a is a liquid crystal (LC) element and the light-emitting element 10b is an electroluminescent (organic EL) element will be described.

Communication between the controller IC 115 and a host 140 is performed through the interface 150. Image data, a variety of control signals, and the like are transmitted from the host 140 to the controller IC 115. Information on a touch position or the like obtained by the touch sensor controller 184 is transmitted from the controller IC 115 to the host 140. Note that the decision whether the circuits included in the controller IC 115 are chosen or not is made as appropriate depending on the standard of the host 140, the specifications of the display device 100, and the like.

The frame memory 151 is a memory for storing the image data input to the controller IC 115. In the case where compressed image data is transmitted from the host 140, the frame memory 151 can store the compressed image data. The decoder 152 is a circuit for decompressing the compressed image data. When decompression of the image data is not needed, processing is not performed in the decoder 152. Alternatively, the decoder 152 can be provided between the frame memory 151 and the interface 150.

The image processing portion 160 is configured to perform various kinds of image processing on image data. For example, the image processing portion 160 includes a gamma correction circuit 161, a dimming circuit 162, a toning circuit 163, and an EL correction circuit 164.

The EL correction circuit 164 is provided in the case where the source driver 182 is provided with a current detection circuit that detects current flowing through the light-emitting element 10b. The EL correction circuit 164 is configured to adjust luminance of the light-emitting element 10b on the basis of a signal transmitted from the current detection circuit of the source driver 182.

The image data processed in the image processing portion 160 is output to the source driver 180 through the memory 170. The memory 170 is a memory for temporarily storing image data. The source driver 181 and the source driver 182 each have a function of processing the input image data and writing the image data to the source line of the pixel array 111.

The timing controller 173 is configured to generate timing signals to be used in the source driver 180, the touch sensor controller 184, and the gate drivers 113 and 114 of the display unit 110.

The touch sensor controller 184 is configured to control the TS driver 126 and the sensing circuit 127 of the touch sensor unit 120. A signal including touch information read from the sensing circuit 127 is processed in the touch sensor controller 184 and transmitted to the host 140 through the interface 150. The host 140 generates image data reflecting the touch information and transmits the image data to the controller IC 115. Note that the controller IC 115 can reflect the touch information in the image data.

The clock generation circuit 155 is configured to generate a clock signal to be used in the controller IC 115. The controller 154 is configured to process a variety of control signals transmitted from the host 140 through the interface 150 and controlling a variety of circuits in the controller IC 115. The controller 154 is also configured to control power supply to the variety of circuits in the controller IC 115. Hereinafter, temporary stop of power supply to a circuit that is not used is referred to as power gating.

The register 175 stores data used for the operation of the controller IC 115. The data stored in the register 175 includes a parameter used to perform correction processing in the image processing portion 160, parameters used to generate waveforms of a variety of timing signals in the timing controller 173, and the like. The register 175 is provided with a scan chain register including a plurality of registers.

The sensor controller 153 is electrically connected to an optical sensor 143. The optical sensor 143 senses external light 145 and generates a sensor signal. The sensor controller 153 generates a control signal on the basis of the sensor signal. The control signal generated in the sensor controller 153 is output to the controller 154, for example.

In the case where the reflective element 10a and the light-emitting element 10b display the same image data, the image processing portion 160 is configured to separately generate image data that the reflective element 10a displays and image data that the light-emitting element 10b displays. In that case, reflection intensity of the reflective element 10a and emission intensity of the light-emitting element 10b can be adjusted in response to brightness of the external light 145 measured using the optical sensor 143 and the sensor controller 153. Here, the adjustment can be referred to as dimming or dimming treatment. In addition, a circuit that performs the dimming treatment is referred to as a dimming circuit.

In the case where the display device 100 is used outside at daytime on a sunny day, it is not necessary to make the light-emitting element 10b emit light if sufficient luminance can be obtained only with the reflective element 10a. This is due to the fact that favorable display cannot be obtained because, even when the light-emitting element 10b is used to perform display, external light exceeds light emitted from the light-emitting element 10b. In contrast, in the case where the display device 100 is used at night or in a dark place, display is performed by making the light-emitting element 10b emit light.

In response to the brightness of external light, the image processing portion 160 can generate image data that only the reflective element 10a displays, image data that only the light-emitting element 10b displays, or image data that the reflective element 10a and the light-emitting element 10b display in combination. The display device 100 can perform favorable display even in an environment with bright external light or an environment with weak external light. Furthermore, power consumption can be reduced by making the light-emitting element 10b emit no light or reducing the luminance of the light-emitting element 10b in the environment with bright external light.

Color tones can be corrected by combining the display by the light-emitting element 10b with the display by the reflective element 10a. A function of measuring the color tones of the external light 145 may be added to the optical sensor 143 and the sensor controller 153 to perform such tone correction. For example, in the case where the display device 100 is used in a reddish environment at evening, a blue (B) component is not sufficient only with the display by the reflective element 10a; thus, the color tones can be corrected by making the light-emitting element 10b emit light. Here, the correction can be referred to as toning or toning treatment. In addition, a circuit that performs the toning treatment is referred to as a toning circuit.

The image processing portion 160 might include another processing circuit such as an RGB-RGBW conversion circuit depending on the specifications of the display device 100. The RGB-RGBW conversion circuit is configured to convert image data of red, green, and blue (RGB) into image data of red, green, blue, and white (RGBW). That is, in the case where the display device 100 includes pixels of four colors of RGBW, power consumption can be reduced by displaying a white (W) component in the image data using the white (W) pixel. Note that the image processing portion 160 may include, for example, a RGB-RGBY (red, green, blue, and yellow) conversion circuit without limitation to the RGB-RGBW conversion circuit.

The reflective element 10a and the light-emitting element 10b can display different image data. In general, operation speed of liquid crystal, electronic paper, or the like that can be used as a reflective element is low in many cases (it takes time to display a picture). Thus, a still image to be a background can be displayed on the reflective element 10a and a moving mouse pointer or the like can be displayed on the light-emitting element 10b. By performing the above IDS driving on a still image and making the light-emitting element 10b emit light to display a moving image, the display device 100 can achieve display of a smooth moving image and reduction of power consumption at the same time. In that case, the frame memory 151 may be provided with regions for storing image data displayed on the reflective element 10a and image data displayed on the light-emitting element 10b.

### <Parameter>

Image correction processing such as gamma correction, dimming, or toning corresponds to processing of generating output correction data Y with respect to input image data X. The parameter that the image processing portion 160 uses is a parameter for converting the image data X into the correction data Y.

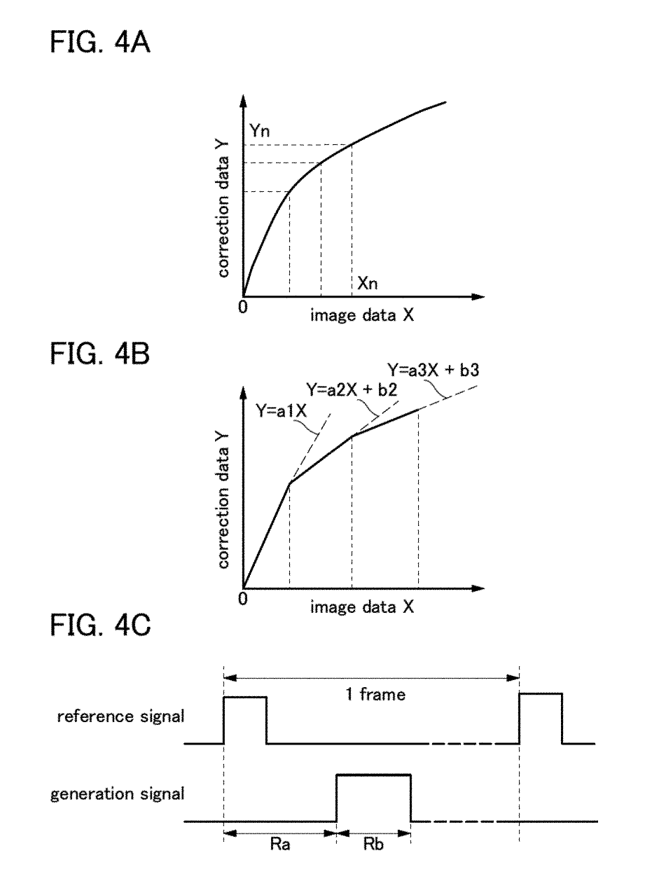

As a parameter setting method, there are a table method and a function approximation method. In a table method shown in FIG. 4A, correction data Yn with respect to image data Xn is stored in a table as a parameter. In the table method, a number of registers for storing the parameters that correspond to the table is necessary; however, correction can be performed with high degree of freedom. In contrast, in the case where the correction data Y with respect to the image data X can be empirically determined in advance, it is effective to employ a function approximation method as shown in FIG. 4B. Note that a1, a2, b2, and the like are parameters. Although a method of performing linear approximation in every period is shown here, a method of performing approximation with a nonlinear function can be employed. In the function approximation method, correction is performed with low degree of freedom; however, the number of registers for storing parameters that defines a function can be small.

The parameter that the timing controller 173 uses indicates timing at which a generation signal of the timing controller 173 becomes “L” (or “H”) with respect to a reference signal as shown in FIG. 4C. A parameter Ra (or Rb) indicates the number of clock cycles that corresponds to timing at which the parameter becomes “L” (or “H”) with respect to the reference signal.

The above parameter for correction can be stored in the register 175. Other parameters that can be stored in the register 175 include data of the EL correction circuit 164, luminance, color tones, and setting of energy saving (time taken to make display dark or turn off display) of the display device 100 which are set by a user, sensitivity of the touch sensor controller 184, and the like.

### <Power Gating>

In the case where image data transmitted from the host 140 is not changed, the controller 154 can power gate some circuits in the controller IC 115. Specifically, for example, the circuits are circuits in a region 190 (the frame memory 151, the decoder 152, the image processing portion 160, the memory 170, the timing controller 173, the register 175, and the source driver 180). Power gating can be performed in the case where a control signal that indicates no change in the image data is transmitted from the host 140 to the controller IC 115 and detected by the controller 154.

The circuits in the region 190 are the circuits relating to image data and the circuits for driving the display unit 110; therefore, the circuits in the region 190 can be temporarily stopped in the case where the image data is not changed. Note that even when the image data is not changed, time during which the transistor used for the pixel 10 can store data (time during which idling stop can be performed) and time during which inversion driving is performed to prevent burn-in of a liquid crystal (LC) element used as the reflective element 10a may be considered.

For example, the controller 154 may be incorporated with a timer function so as to determine timing at which power supply to the circuits in the region 190 is restarted, on the basis of time measured by a timer. Note that it is possible to store image data in the frame memory 151 or the memory 170 in advance and supply the image data to the display unit 110 at inversion driving. With such a structure, inversion driving can be performed without transmitting the image data from the host 140. Thus, the amount of data transmitted from the host 140 can be reduced and power consumption of the controller IC 115 can be reduced.

Specific circuit configurations of the frame memory 151 and the register 175 will be described below. Note that the circuits that can be power gated are not limited to the circuits in the region 190, the sensor controller 153, the touch sensor controller 184, and the like, which are described here. A variety of combinations can be considered depending on the configuration of the controller IC 115, the standard of the host 140, the specifications of the display device 100, and the like.

### <Frame Memory 151>

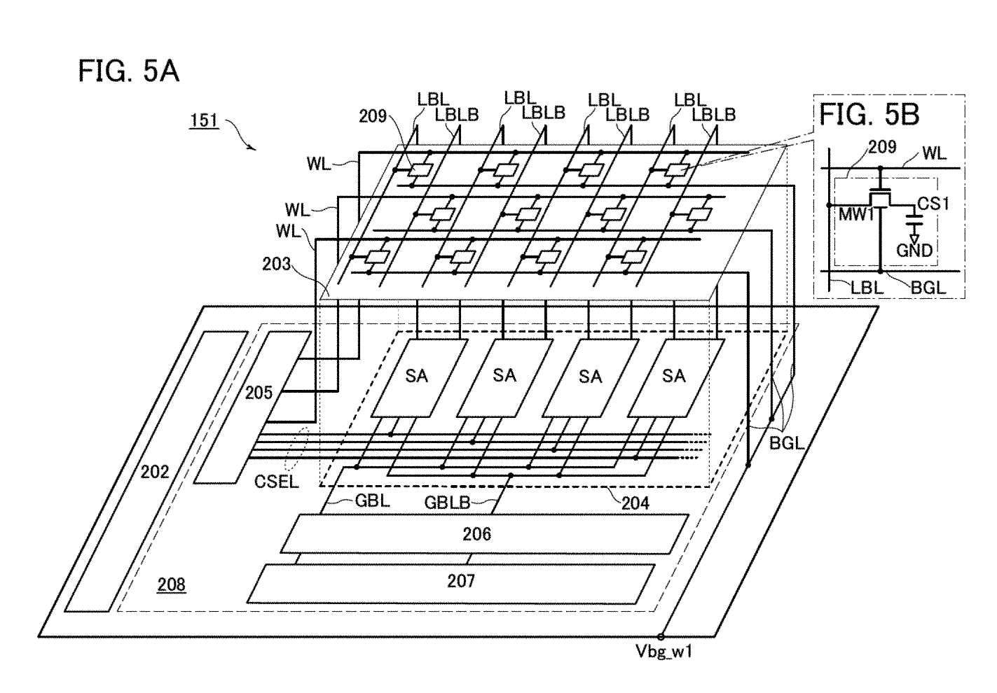

FIG. 5A illustrates a configuration example of the frame memory 151. The frame memory 151 includes a control portion 202, a cell array 203, and a peripheral circuit 208. The periphery circuit 208 includes a sense amplifier circuit 204, a driver 205, a main amplifier 206, and an input output circuit 207.

The control portion 202 is configured to control the frame memory 151. For example, the control portion 202 controls the driver 205, the main amplifier 206, and the input output circuit 207.

The driver 205 is electrically connected to a plurality of wirings WL and CSEL. The driver 205 generates signals output to the plurality of wirings WL and CSEL.

The memory cell array 203 includes a plurality of memory cells 209. The memory cells 209 are electrically connected to wirings WL, LBL (or LBLB), and BGL. The wiring WL is a word line. The wirings LBL and LBLB are local bit lines. Although a folded-bit-line method is employed for the configuration of the cell array 203 in the example of FIG. 5A, an open-bit-line method can also be employed.

FIG. 5B illustrates a configuration example of the memory cell 209. The memory cell 209 includes a transistor MW1 and a capacitor CS1. The memory cell 209 has a circuit configuration similar to that of a memory cell for a dynamic random access memory (DRAM). The transistor MW1 in this example is a transistor having a back gate. The back gate of the transistor MW1 is electrically connected to a wiring BGL. A voltage Vbg_w1 is input to the wiring BGL.

The transistor MW1 is a transistor including an oxide semiconductor in a channel formation region (such a transistor is also referred to as an “OS transistor”). Since an OS transistor has an extremely low off-state current, the frequency of refresh operation of the frame memory 151 can be reduced because leakage of charge from the capacitor CS1 can be suppressed by forming the memory cell 209 using an OS transistor. The frame memory 151 can retain image data for a long time even when power supply is stopped. Moreover, by setting the voltage Vbg_w1 to a negative voltage, the threshold voltage of the transistor MW1 can be shifted to the positive potential side and thus the retention time of the memory cell 209 can be increased.

Here, an off-state current refers to a current that flows between a source and a drain of a transistor in an off state. In the case of an n-channel transistor, for example, when the threshold voltage of the transistor is approximately 0 V to 2 V, a current flowing between a source and a drain when a voltage of a gate with respect to the source is negative can be referred to as an off-state current. An extremely low off-state current means that, for example, an off-state current per micrometer of channel width is lower than or equal to 100 zA (z represents zepto and denotes a factor of 10⁻²¹). Since the off-state current is preferably as low as possible, the normalized off-state current is preferably lower than or equal to 10 zA/μm or lower than or equal to 1 zA/μm), further preferably lower than or equal to 10 yA/μm (y represents yocto and denotes a factor of 10⁻²⁴).

An oxide semiconductor has a bandgap of 3.0 eV or higher; thus, an OS transistor has a low leakage current due to thermal excitation and, as described above, has an extremely low off-state current. An oxide semiconductor used as a channel formation region of an OS transistor is preferably an oxide semiconductor containing at least one of indium (In) and zinc (Zn). Typical examples of such an oxide semiconductor include an In-M-Zn oxide (M is Al, Ga, Y, or Sn, for example). By reducing impurities serving as electron donors, such as moisture or hydrogen, and also reducing oxygen vacancies, an i-type (intrinsic) or a substantially i-type oxide semiconductor can be obtained. Here, such an oxide semiconductor can be referred to as a highly-purified oxide semiconductor. For example, by using a highly purified oxide semiconductor in a channel formation region, the off-state current of the OS transistor that is normalized by channel width can be as low as approximately several yoctoamperes per micrometer to several zeptoamperes per micrometer.

The transistors MW1 in the plurality of memory cells 209 included in the cell array 203 are OS transistors; thus, Si transistors formed over a silicon wafer can be used as transistors in other circuits, for example. Accordingly, the cell array 203 can be stacked over the sense amplifier circuit 204. Thus, the circuit area of the frame memory 151 can be reduced, which leads to miniaturization of the controller IC 115.

The cell array 203 is stacked over the sense amplifier circuit 204. The sense amplifier circuit 204 includes a plurality of sense amplifiers SA. The sense amplifiers SA are electrically connected to adjacent wirings LBL and LBLB (a pair of local bit lines), wirings GBL and GBLB (a pair of global bit lines), and the plurality of wirings CSEL. The sense amplifiers SA have a function of amplifying the potential difference between the wirings LBL and LBLB.

In the sense amplifier circuit 204, one wiring GBL is provided for four wirings LBL, and one wiring GBLB is provided for four wirings LBLB. However, the configuration of the sense amplifier circuit 204 is not limited to the configuration example of FIG. 5A.

The main amplifier 206 is connected to the sense amplifier circuit 204 and the input output circuit 207. The main amplifier 206 is configured to amplify the potential difference between the wirings GBL and GBLB. The main amplifier 206 is not necessarily provided.

The input/output circuit 207 is configured to output a potential corresponding to a write data to the wirings GBL and GBLB or the main amplifier 206 and a function of outputting the potentials of the wirings GBL and GBLB or an output potential of the main amplifier 206 to the outside as read data. The sense amplifier SA from which data is read and the sense amplifier SA to which data is written can be selected in accordance with the signal of the wiring CSEL. Therefore, there is no need to provide a selection circuit such as a multiplexer in the input/output circuit 207. Thus, the input/output circuit 207 can have a simple circuit configuration and a small occupied area.

### <Register 175>

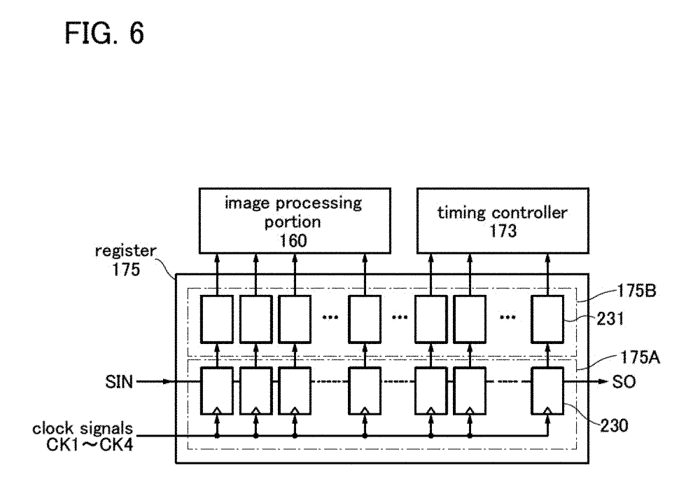

FIG. 6 is a block diagram illustrating a configuration example of the register 175. The register 175 includes a scan chain register portion 175A and a register portion 175B. The scan chain register portion 175A includes a plurality of registers 230. The scan chain register is formed by the plurality of registers 230. The register portion 175B includes a plurality of registers 231.

The register 230 is a nonvolatile register which can retain data for a long time even when power supply is stopped. Here, the register 230 is configured with an OS transistor so as to be nonvolatile. In contrast, the register 231 is configured with a volatile register including a Si transistor and a circuit including an OS transistor.

The image processing portion 160 and the timing controller 173 access the register portion 175B and take data from the corresponding registers 231. Alternatively, the processing contents of the image processing portion 160 and the timing controller 173 are controlled in accordance with data supplied from the register portion 175B.

There is no particular limitation on the circuit configuration of the register 231, and a latch circuit, a flip-flop circuit, or the like is used as long as data can be stored. Alternatively, as with the register 230, the register 231 may use only an OS transistor, while it is preferable that the register 231 be capable of reducing the change in potential when accessed by the image processing portion 160 and the timing controller 173. In other words, it is preferable that the register 231 be capable of outputting a signal.

To update data stored in the register 175, first, data in the scan chain register portion 175A are changed. After the data in the registers 230 of the scan chain register portion 175A are rewritten, the data are loaded into the registers 231 of the register portion 175B at the same time.

Accordingly, the image processing portion 160, the timing controller 173, and the like can perform various kinds of processing using the data which are updated at the same time. The operation of the controller IC 115 can be stable because simultaneity can be maintained in updating data. By providing the scan chain register portion 175A and the register portion 175B, data in the scan chain register portion 175A can be updated even during the operation of the image processing portion 160 and the timing controller 173.

In performing the power gating of the controller IC 115, after the power supply is restored, the data in the register 230 is restored (loaded) to the register 231 to resume normal operation. In the case where the data stored in the register 230 does not match with the data stored in the register 231, it is preferable to save the data stored in the register 231 to the register 230. For example, while updated data is being stored in the scan chain register portion 175A, the data do not match each other.

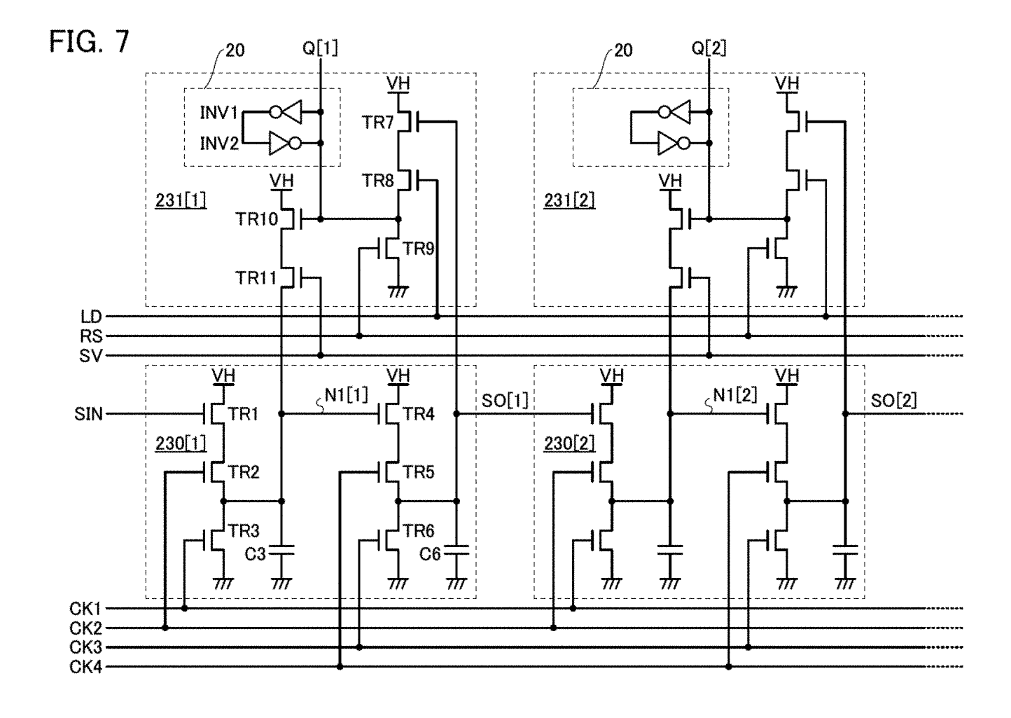

FIG. 7 illustrates an example of a circuit configuration of the register 230 and the register 231. FIG. 7 illustrates a first register 230[1] and a second register 230[2] of the scan chain register portion 175A and corresponding two registers 231[1] and 231[2].

The register 230 includes transistors TR1 to TR6, and capacitors C3 and C6. The transistors TR1 to TR6 are OS transistors. The transistors TR1 to TR6 may each be an OS transistor having a back gate, as with the transistor MW1 of the memory cell 209 (see FIG. 5B).

The register 231 includes transistors TR7 to TR11 and inverters INV1 and INV2. For example, the transistors TR7 to TR11 may be OS transistors, and the inverters INV1 and INV2 in the region 20 may be formed using a Si transistor. Alternatively, the transistors TR7 to TR11 may be Si transistors, and the inverters INV1 and INV2 may be formed using a Si transistor.

The registers 230 and 231 receive a low power supply potential and a high power supply potential. In FIG. 7, the lower power supply potential is represented by a ground potential, and the high power supply potential is represented by VH. The register 230 receives clock signals CK1 to CK4, and the register 231 receives signals LD, RS, and SV. The first register 230[1] receives data SIN from the outside and outputs a signal SO[1]; the second register 230[2] receives the signal SO[1] and outputs a signal SO[2].

The register 231[1] corresponding to the register 230[1] outputs a signal Q[1], and the register 231[2] corresponding to the register 230[2] outputs a signal Q[2]. The signal Q[1] and the signal Q[2] are data that are output to the image processing portion 160, the timing controller 173, and the like.

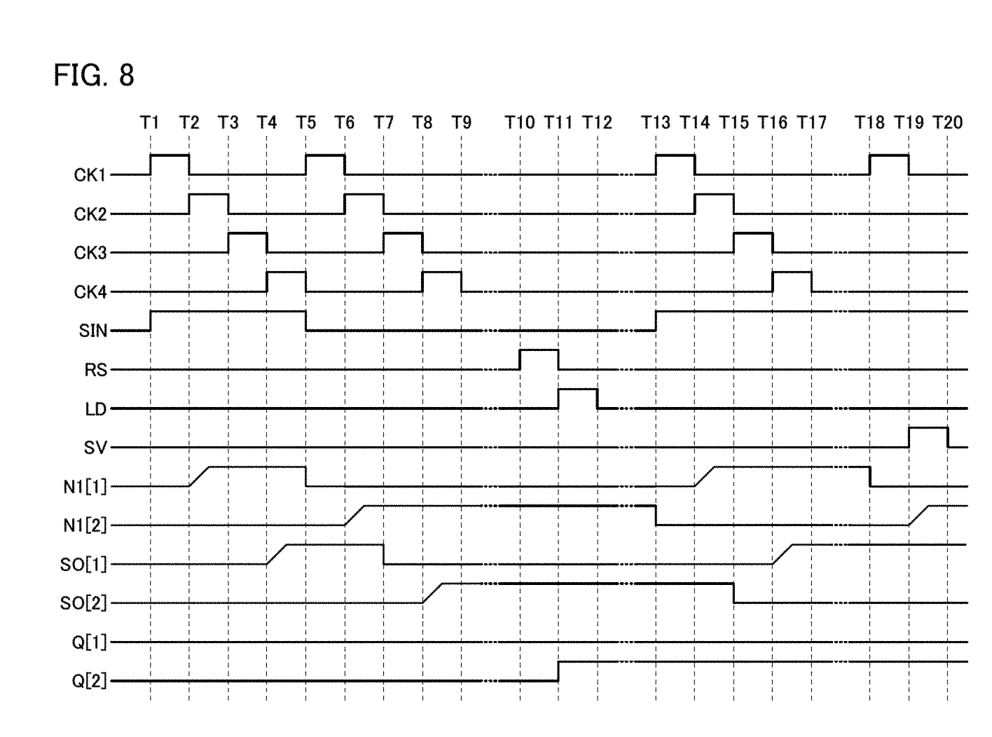

FIG. 8 illustrates the relationships between the clock signals CK1 to CK4, the signals LD, RS, and SV, the data SIN, and the input/output signals SO[1], SO[2], Q[1], and Q[2]. FIG. 8 is a timing chart illustrating an operation example of the registers 230 and 231.

In FIG. 8, a period from a time T1 to a time T9 is a period in which data is stored in the scan chain register portion 175A, a period from a time T10 to a time T12 is a period in which the data stored in the scan chain register portion 175A is loaded to the register portion 175B, a period from a time T13 to a time T17 is a period in which the data is being stored again in the scan chain register portion 175A, and a period from a time T18 to a time T20 is a period in which the data stored in the register portion 175B is saved to the scan chain register portion 175A.

In a period from the time T1 to the time T2, setting the clock signal CK1 to “H” (a high level) resets a node N1[1] of the register 230[1] and a node N1[2] of the register 230[2] to “L” (a low level). In a period from the time T2 to the time T3, setting the clock signal CK2 to “H” sets the node N1[1] of the register 230[1] to “H” that is a value corresponding to the data SIN, and the node N1[2] of the register 230[2] to “L” that is a value corresponding to the SO[1].

In a period from the time T3 to the time T4, setting the clock signal CK3 to “H” resets the output signal SO[1] of the register 230[1] and the output signal SO[2] of the register 230[2] to “L”. In a period from the time T4 to the time T5, setting the clock signal CK4 to “H” sets the output signal SO[1] of the register 230[1] to “H” that is a value corresponding to the node N1[1], and the output signal SO[2] of the register 230[2] to “L” that is a value corresponding to the node N1[2].

In a period from the time T5 to the time T6, setting the clock signal CK1 to “H” resets the node N1[1] of the register 230[1] and the node N1[2] of the register 230[2] to “L”. In a period from the time T6 to the time T7, setting the clock signal CK2 to “H” sets the node N1[1] of the register 230[1] to “L” that is a value corresponding to the data SIN, and the node N1[2] of the register 230[2] to the “H” that is a value corresponding to the SO[1].

In a period from the time T7 to the time T8, setting the clock signal CK3 to “H” resets the output signal SO[1] of the register 230[1] and the output signal SO[2] of the register 230[2] to “L”. In a period from the time T8 to the time T9, setting the clock signal CK4 to “H” sets the output signal SO[1] of the register 230[1] to “L” that is a value corresponding to the node N1[1], and the output signal SO[2] of the register 230[2] to “H” that is a value corresponding to the node N1[2].

In this manner, the operation in the period from the time T1 to the time T9 sets the output signal SO[1] of the register 230[1] to “L”, and the output signal SO[2] of the register 230[2] to “H”, so that data can be stored in the register 230 included in the scan chain register portion 175A. The values of the SO[1] and the SO[2] can be changed by changing the data SIN.

Subsequently, in a period from the time T10 to the time T11, setting the signal RS to “H” resets the output signal Q[1] of the register 231[1] and the output signal Q[2] of the register 231[2] to “L”. In a period from the time T11 to the time T12, setting the signal LD to “H” sets the output signal Q[1] of the register 231[1] to “L” that is a value corresponding to the SO[1], and the output signal Q[2] of the register 231[2] to “H” that is a value corresponding to the SO[2].

The operation in the period from the time T10 to the time T12 sets the output signal Q[1] of the register 231[1] to “L” and the output signal Q[2] of the register 231[2] to “H”, so that the data of scan chain register portion 175A can be loaded to the register 231 included in the register portion 175B.

Note that the capacitors C3 and C6 included in the register 230 are each connected to an OS transistor with an extremely low off-state current, and thus can retain charge for a long period even when power supply is stopped. Even when the data in the register 231 is lost because of stopping power supply, after the restart of the power supply, the above-described operation in the period from the time T10 to the time T12 enables the data in the scan chain register portion 175A to be loaded to the register portion 175B.

Subsequently, in the period from the time T13 to the time T17, the data is re-stored in the scan chain register portion 175A. The operation is the same as that in the period from the time T1 to the time T5 and thus the description thereof is omitted here; the output signal SO[1] of the register 230[1] is set to “H” and the output signal SO[2] of the register 230[2] is set to “L”.

In the case where the power supply is stopped, the output signal SO[1] of the register 230[1] and the output signal SO[2] of the register 230[2] are different from the signals of the register 231 loaded by the operation in the period from the time T10 to the time T12 (the Q[1] is “L” and the Q[2] is “H”); thus, it is preferable to save the data in the register portion 175B to the scan chain register portion 175A.

In a period from the time T18 to the time T19, setting the clock signal CK1 to “H” resets the node N1[1] of the register 230[1] and the node N1[2] of the register 230[2] to “L”. In a period from the time T19 to the time T20, setting the signal SV to “H” sets the node N1[1] of the register 230[1] to “L” that is a value corresponding to the Q[1], and the node N1[2] of the register 230[2] to “H” that is a value corresponding to the Q[2].

Subsequently, sequentially setting the clock signal CK3 and the clock signal CK4 to “H” sets the output signal SO[1] of the register 230[1] to “L” that is a value corresponding to the node N1[1], and the output signal SO[2] of the register 230[2] to “H” that is a value corresponding to the node N1[2]; the description and the diagram thereof are the same as those of the period from the time T7 to the time T9, and thus are omitted.

As described above, in the case where the power supply is stopped while the data in the scan chain register portion 175A is updated, the data in the scan chain register portion 175A and the data in the register portion 175B do not match with each other. When the power supply is restarted, unmatched data are loaded to the register portion 175B; thus, it is preferable to save the data to the register portion 175B to the scan chain register portion 175A. Alternatively, the power supply may be stopped after the data in the scan chain register portion 175A is updated.

### <Another Configuration Example of Controller IC>

Another configuration example of a controller IC will be described below.

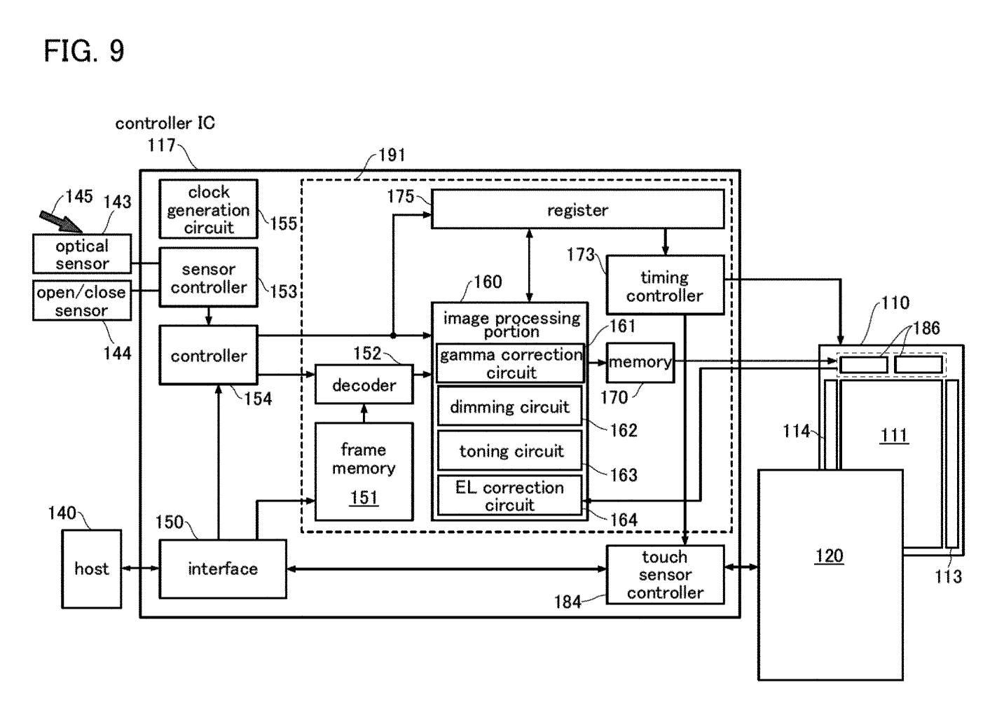

FIG. 9 illustrates a configuration example of a controller IC without a source driver. A controller IC 117 in FIG. 9 is a modification example of the controller IC 115 and includes a region 191. The controller 154 controls power supply to circuits in the region 191.

The region 191 is not provided with a source driver. Thus, the display unit 110 includes a source driver IC 186. The number of source driver ICs 186 is determined in accordance with the number of pixels of the pixel array 111.

The source driver IC 186 is configured to drive both the reflective element 10a and the light-emitting element 10b. Although the source driver is formed using only one kind of source driver IC 186, the configuration of the source driver is not limited thereto. For example, the source driver may be formed using a source driver IC for driving the reflective element 10a and a source driver IC for driving the light-emitting element 10b.

Similar to the gate driver 113 and the gate driver 114, the source drivers may be formed over a substrate of the pixel array 111.

The controller IC 117 may be provided with one or both of the TS driver 126 and the sensing circuit 127. The same applies to the controller IC 115.

### <<Operation Example>>

Operation examples of the controller IC 115 and the register 175 of the display device 100 before shipment, at boot-up of an electronic device including the display device 100, and at normal operation will be described separately.

### <Before Shipment>

Parameters relating to the specifications and the like of the display device 100 are stored in the register 175 before shipment. These parameters include, for example, the number of pixels, the number of touch sensors, parameters used to generate waveforms of the variety of timing signals in the timing controller 173, and correction data of the EL correction circuit 164 in the case where the source driver 182 is provided with the current detection circuit that detects current flowing through the light-emitting element 10b. These parameters may be stored by providing a dedicated ROM other than the register 175.

### <At Boot-Up>

At boot-up of an electronic device including the display device 100, the parameters set by a user or the like which are transmitted from the host 140 are stored in the register 175. These parameters include, for example, luminance, color tones, sensitivity of a touch sensor, setting of energy saving (time taken to make display dark or turn off display), and a curve or a table for gamma correction. Note that in storing the parameters in the register 175, clock signals CK1 to CK4 and data corresponding to the parameters in synchronization with the clock signals CK1 to CK4 are transmitted from the controller 154 to the register 175.

### <Normal Operation>

Normal operation can be classified into a state of displaying a moving image or the like, a state capable of performing IDS driving while a still image is displaying, a state of displaying no image, and the like. The image processing portion 160, the timing controller 173, and the like are operating in the state of displaying a moving image or the like; however, the image processing portion 160 and the like are not influenced because only the data of the register 175 in the scan chain register portion 175A are changed. After the data of the scan chain register portion 175A are changed, the data of the scan chain register portion 175A are loaded in the register portion 175B at the same time, so that change of the data of the register 175 is completed. The operation of the image processing portion 160 and the like is switched to the operation corresponding to the data.

In the state capable of performing IDS driving while a still image is displaying, the register 175 can be power gated in a manner similar to that of the other circuits in the region 190. In this case, if the data in the scan chain register portion 175A is being updated, it is preferable that the data in the register portion 175B be saved in the scan chain register portion 175A.

In restoring from the power gating, following the signals RS and LD, the data in the scan chain register portion 175A is loaded to the register portion 175B. In this manner, the data of the register 175 becomes effective in the same state as before the power gating. Note that even when the register 175 is in a state of power gating, the parameter of the register 175 can be changed by canceling the power gating in the case where change of the parameter is requested by the host 140.

In the state of displaying no image, for example, the circuits (including the register 175) in the region 190 can be power gated. In that case, the operation of the host 140 might also be stopped; however, when the data in the frame memory 151 and the register 175 are restored from the power gating, the frame memory 151 and the register 175 can perform display (a still image) before power gating without waiting the restore of the host 140 because they are nonvolatile.

For example, in the case where the display device 100 is employed for a display portion of a foldable cellular phone, when the cellular phone is folded and the display surface of the display device 100 is sensed to be unused by a signal from an open/close sensor 144, the sensor controller 153, the touch sensor controller 184, and the like can be power gated in addition to the circuits in the region 190.

When the cellular phone is folded, the operation of the host 140 might be stopped depending on the standard of the host 140. Even when the cellular phone is unfolded while the operation of the host 140 is stopped, the image data in the frame memory 151 can be displayed before image data, a variety of control signals, and the like are transmitted from the host 140 because the frame memory 151 and the register 175 are nonvolatile.

In the above manner, the register 175 includes the scan chain register portion 175A and the register portion 175B and data of the scan chain register portion 175A are changed, so that the parameter can be changed smoothly without influencing the image processing portion 160, the timing controller 173, and the like. Each of the registers 230 in the scan chain register portion 175A is a nonvolatile register using an OS transistor, and thus can readily power gate on the basis of the operating states of the display device. In addition, since the frame memory 151 is also nonvolatile, the display can be restarted immediately when the power supply is restarted. The transition to and the restoration from a power-gating state can be performed smoothly, thereby achieving a system capable of reducing power consumption.

### Embodiment 2

In this embodiment, details of the display unit 110 described in Embodiment 1 will be described.

### <Configuration Example Display Panel>

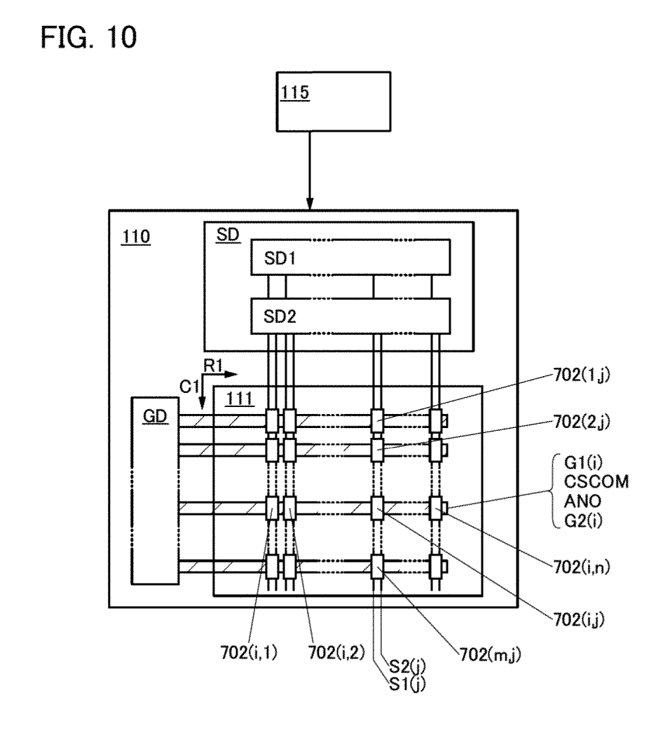

FIG. 10 is a block diagram illustrating a configuration example of the display unit 110.

The display unit 110 includes the pixel array 111. The display unit 110 can include a gate driver GD or a source driver SD.

### <<Pixel Array 111>>

The pixel array 111 includes one group of pixels 702(i, 1) to 702(i, n), another group of pixels 702(1, j) to 702(m, j), and a scan line G1(i). In addition, a scan line G2(i), a wiring CSCOM, a wiring ANO, and a signal line S2(j) are provided. Note that i is an integer greater than or equal to 1 and less than or equal to m, j is an integer greater than or equal to 1 and less than or equal to n, and each of m and n is an integer greater than or equal to 1.

The one group of pixels 702(i, 1) to 702(i, n) include the pixel 702(i, j) and are provided in the row direction (the direction indicated by the arrow R1 in the drawing).

The another group of pixels 702(1, j) to 702(m, j) include the pixel 702(i, j) and are provided in the column direction (the direction indicated by the arrow C1 in the drawing) that intersects the row direction.

The scan line G1(i) and the scan line G2(i) are electrically connected to the group of pixels 702(i, 1) to 702(i, n) provided in the row direction.

The signal line Si (j) and the signal line S2 (j) are electrically connected to the another group of the pixels 702(1, j) to 702(m, j) arranged in the column direction.

### <<Gate Driver GD>>

The gate driver GD is configured to supply a selection signal on the basis of control data.

For example, the driver circuit GD is configured to supply a selection signal to one scan line at a frequency of 30 Hz or higher, preferably 60 Hz or higher, in accordance with the control information. Accordingly, moving images can be smoothly displayed.

For example, the driver circuit GD is configured to supply a selection signal to one scan line at a frequency of lower than 30 Hz, preferably lower than 1 Hz, more preferably less than once per minute, in accordance with the control information. Accordingly, a still image can be displayed while flickering is suppressed.

### <<Source Driver SD, Source Driver SD1, and Source Driver SD2>>

The source driver SD includes a source driver SD1 and a source driver SD2. The source driver SD1 and the source driver SD2 have a function of supplying a data signal on the basis of a signal from the controller IC 115.

The source driver SD1 is configured to generate a data signal that is to be supplied to a pixel circuit electrically connected to one display element. Specifically, the driver circuit SD1 is configured to generate a signal whose polarity is inverted. Thus, for example, a liquid crystal display element can be driven.

The source driver SD2 is configured to generate a data signal that is supplied to a pixel circuit electrically connected to another display element (hereinafter also referred to as a second display element) which displays an image by a method different from that of the one display element. The driver circuit SD2 can drive, for example, an organic EL element.

For example, a variety of sequential circuits, such as a shift register, can be used for the source driver SD.

For example, an integrated circuit in which the source driver SD1 and the source driver SD2 are integrated can be used for the source driver SD. Specifically, an integrated circuit formed over a silicon substrate can be used for the source driver SD.

The source driver SD may be included in the same integrated circuit as the controller IC 115. Specifically, an integrated circuit formed over a silicon substrate can be used for each of the controller IC 115 and the source driver SD.

For example, the above integrated circuit can be mounted by a chip on glass (COG) method or a chip on film (COF) method. Specifically, an anisotropic conductive film can be used to mount an integrated circuit on a terminal.

### <<Pixel Circuit>>

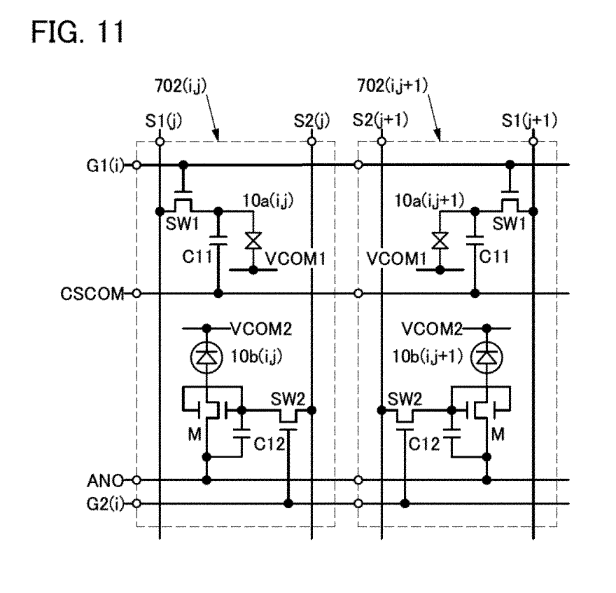

FIG. 11 is a circuit diagram illustrating configuration examples of pixels 702. The pixel 702(i, j) is configured to drive a reflective element 10a(i, j) and a light-emitting element 10b(i, j). Accordingly, the reflective element 10a and the light-emitting element 10b which perform display using a different method from that of the reflective element 10a can be driven, for example, with the pixel circuit which can be formed in the same process. The display performed using the reflective element 10a, which is a reflective display element, can be performed with lower power consumption. In addition, an image with high contrast can be favorably displayed in an environment with bright external light. With the use of the light-emitting element 10b, which is a light-emitting display element, images can be favorably displayed in a dark environment.

The pixel 702(i, j) is electrically connected to the signal line S1(j), the signal line S2(j), the scan line G1(i), the scan line G2(i), the wiring CSCOM, and the wiring ANO.

The pixel 702(i, j) includes a switch SW1, a capacitor C11, a switch SW2, a transistor M, and a capacitor C12.

A transistor including a gate electrode electrically connected to the scan line G1(i) and a first electrode electrically connected to the signal line S1(j) can be used for the switch SW1.

The capacitor C11 includes a first electrode electrically connected to a second electrode of the transistor used as the switch SW1 and a second electrode electrically connected to the wiring CSCOM.

A transistor including a gate electrode electrically connected to the scan line G2(i) and a first electrode electrically connected to the signal line S2(j) can be used for the switch SW2.

The transistor M includes a gate electrode electrically connected to a second electrode of the transistor used for the switch SW2 and a first electrode electrically connected to the wiring ANO.

Note that the transistor M may include a first gate electrode and a second gate electrode. The first gate electrode and the second gate electrode may be electrically connected to each other. The first gate electrode and the second gate electrode preferably have regions overlapping with each other with a semiconductor film positioned therebetween.

The capacitor C12 includes a first electrode electrically connected to a second electrode of the transistor used as the switch SW2 and a second electrode electrically connected to the first electrode of the transistor M.

A first electrode of the reflective element 10a(i, j) is electrically connected to the second electrode of the transistor used as the switch SW1. A second electrode of the reflective element 10a(i, j) is electrically connected to a wiring VCOM1. This enables the reflective element 10a(i, j) to be driven.

A first electrode of the light-emitting element 10b(i, j) is electrically connected to the second electrode of the transistor M. A second electrode of the light-emitting element 10b(i, j) is electrically connected to a wiring VCOM2. This enables the light-emitting element 10b(i, j) to be driven.

### <Top View of Display Panel>

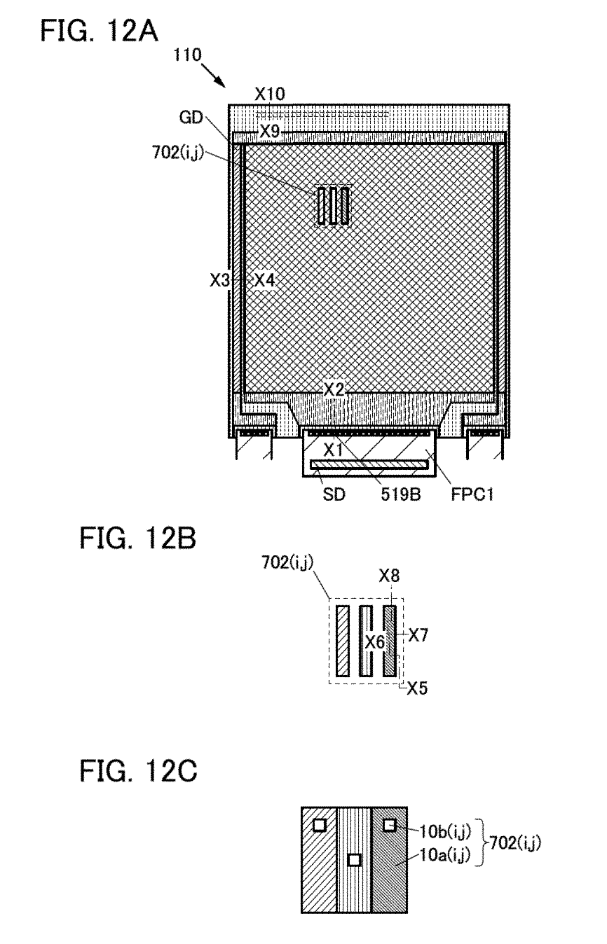

FIGS. 12A to 12C illustrate the structure of the display unit 110. FIG. 12A is a top view of the display unit 110. FIG. 12B is a top view illustrating one pixel of the display unit 110 illustrated in FIG. 12A. FIG. 12C is a schematic view illustrating the structure of the pixel illustrated in FIG. 12B.

In the example in FIG. 12A, the source driver SD and a terminal 519B are provided over a flexible printed circuit FPC1.

The pixel 702(i, j) in FIG. 12C includes the reflective element 10a(i, j) and the light-emitting element 10b(i, j).

### <Cross-Sectional View of Display Panel>

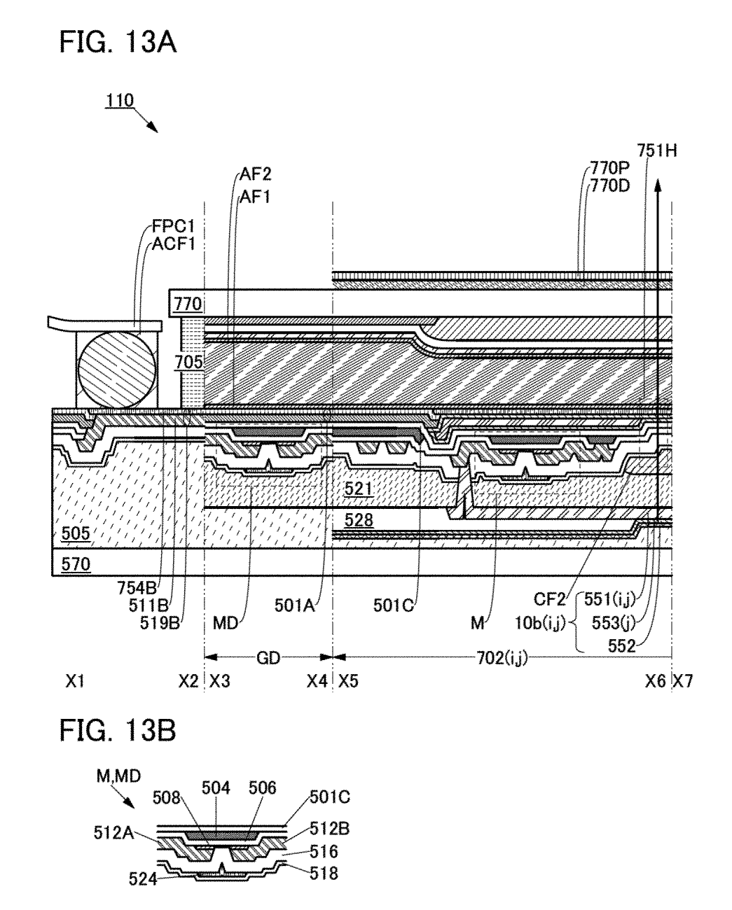

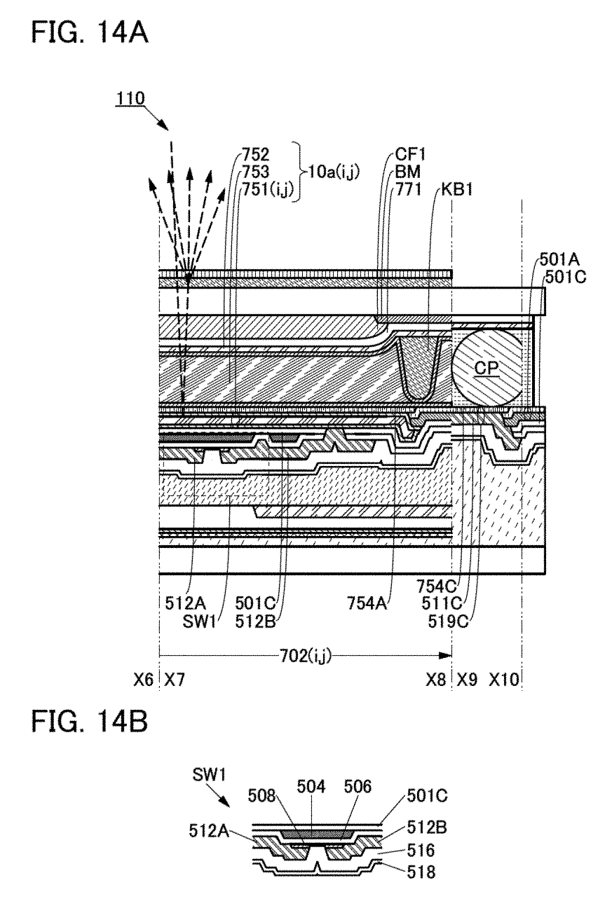

FIGS. 13A and 13B and FIGS. 14A and 14B are cross-sectional views illustrating the structure of the display unit 110. FIG. 13A is a cross-sectional view taken along lines X1-X2 and X3-X4 in FIG. 12A, and X5-X6 in FIG. 12B, and FIG. 13B illustrates part of FIG. 13A.

FIG. 14A is a cross-sectional view taken along lines X7-X8 in FIG. 12B and X9-X10 in FIG. 12A, and FIG. 14B illustrates part of FIG. 14A.

Components of the display unit 110 will be described with reference to FIGS. 13A and 13B and FIGS. 14A and 14B.

### <<Substrate 570>>

The substrate 570 or the like can be formed using a material having heat resistance high enough to withstand heat treatment in the manufacturing process. For example, a material with a thickness greater than or equal to 0.1 mm and less than or equal to 0.7 mm can be used for the substrate 570. Specifically, a material polished to a thickness of approximately 0.1 mm can be used.

For example, a large-sized glass substrate having any of the following sizes can be used as the substrate 570 or the like: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

For the substrate 570 or the like, an organic material, an inorganic material, a composite material of an organic material and an inorganic material, or the like can be used. For example, an inorganic material such as glass, ceramic, or metal can be used for the substrate 570 or the like.

Specifically, non-alkali glass, soda-lime glass, potash glass, crystal glass, aluminosilicate glass, tempered glass, chemically tempered glass, quartz, sapphire, or the like can be used for the substrate 570 or the like. Specifically, an inorganic oxide film, an inorganic nitride film, an inorganic oxynitride film, or the like can be used for the substrate 570 or the like. For example, a silicon oxide film, a silicon nitride film, a silicon oxynitride film, an aluminum oxide film, or the like can be used for the substrate 570 or the like. Stainless steel, aluminum, or the like can be used for the substrate 570 or the like.

For example, a single crystal semiconductor substrate or a polycrystalline semiconductor substrate of silicon or silicon carbide, a compound semiconductor substrate of silicon germanium or the like, or an SOI substrate can be used as the substrate 570 or the like. Thus, a semiconductor element can be provided over the substrate 570 or the like.

For example, an organic material such as a resin, a resin film, or plastic can be used for the substrate 570 or the like. Specifically, a resin film or resin plate of polyester, polyolefin, polyamide, polyimide, polycarbonate, an acrylic resin, or the like can be used for the substrate 570 or the like.

For example, a composite material formed by attaching a metal plate, a thin glass plate, or a film of an inorganic material to a resin film or the like can be used for the substrate 570 or the like. For example, a composite material formed by dispersing a fibrous or particulate metal, glass, inorganic material, or the like into a resin film can be used for the substrate 570 or the like. For example, a composite material formed by dispersing a fibrous or particulate resin, organic material, or the like into an inorganic material can be used for the substrate 570 or the like.

Furthermore, a single-layer material or a layered material in which a plurality of layers are stacked can be used for the substrate 570 or the like. For example, a layered material in which a base, an insulating film that prevents diffusion of impurities contained in the base, and the like are stacked can be used for the substrate 570 or the like. Specifically, a layered material in which glass and one or a plurality of films that are selected from a silicon oxide layer, a silicon nitride layer, a silicon oxynitride layer, and the like and that prevent diffusion of impurities contained in the glass are stacked can be used for the substrate 570 or the like. Alternatively, a layered material in which a resin and a film for preventing diffusion of impurities that penetrate the resin, such as a silicon oxide film, a silicon nitride film, and a silicon oxynitride film are stacked can be used for the substrate 570 or the like.

Specifically, a resin film, a resin plate, a stacked-layer material, or the like containing polyester, polyolefin, polyamide, polyimide, polycarbonate, an acrylic resin, or the like can be used as the substrate 570 or the like.

Specifically, a material including polyester, polyolefin, polyamide (e.g., nylon or aramid), polyimide, polycarbonate, an acrylic resin, a urethane resin, an epoxy resin, a resin having a siloxane bond, such as silicone, or the like can be used for the substrate 570 or the like.

Specifically, polyethylene terephthalate (PET), polyethylene naphthalate (PEN), polyethersulfone (PES), an acrylic resin, or the like can be used for the substrate 570 or the like. Alternatively, a cyclo olefin polymer (COP), a cyclo olefin copolymer (COC), or the like can be used.

Alternatively, paper, wood, or the like can be used for the substrate 570 or the like.

For example, a flexible substrate can be used as the substrate 570 or the like.

Note that a transistor, a capacitor, or the like can be directly formed on the substrate. Alternatively, a transistor, a capacitor, or the like formed on a substrate for use in manufacturing processes which can withstand heat applied in the manufacturing process can be transferred to the substrate 570 or the like. Thus, a transistor, a capacitor, or the like can be formed over a flexible substrate, for example.

### <<Substrate 770>>

For example, a light-transmitting material can be used for the substrate 770. Specifically, any of the materials that can be used for the substrate 570 can be used for the substrate 770.

For example, aluminosilicate glass, tempered glass, chemically tempered glass, sapphire, or the like can be favorably used for the substrate 770 that is on a side closer to a user of the display panel. This can prevent breakage or damage of the display panel caused by the use.

A material with a thickness greater than or equal to 0.1 mm and less than or equal to 0.7 mm can be also used for the substrate 770, for example. Specifically, a substrate polished for reducing the thickness can be used. Thus, a functional film 770D can be provided so as to be close to the reflective element 10a(i, j). As a result, image blur can be reduced and an image can be displayed clearly.

### <<Structure Body KB1>>

The structure body KB1 or the like can be formed using an organic material, an inorganic material, or a composite material of an organic material and an inorganic material. Accordingly, a predetermined space can be provided between components between which the structure KB1 and the like are provided.

Specifically, for the structure KB1, polyester, polyolefin, polyamide, polyimide, polycarbonate, polysiloxane, an acrylic resin, or the like, or a composite material of a plurality of resins selected from these can be used. Alternatively, a photosensitive material may be used.

### <<Sealing Material 705>>

For the sealant 705 or the like, an inorganic material, an organic material, a composite material of an inorganic material and an organic material, or the like can be used.

For example, an organic material such as a thermally fusible resin or a curable resin can be used for the sealant 705 or the like.

For example, an organic material such as a reactive curable adhesive, a light curable adhesive, a thermosetting adhesive, and/or an anaerobic adhesive can be used for the sealant 705 or the like.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, or the like can be used for the sealant 705 or the like.

### <<Bonding Layer 505>>

For example, any of the materials that can be used for the sealant 705 can be used for a bonding layer 505.

### <<Insulating Film 521 and Insulating Film 518>>

For example, an insulating inorganic material, an insulating organic material, or an insulating composite material containing an inorganic material and an organic material can be used for insulating films 521 and 518 and the like.

Specifically, for example, an inorganic oxide film, an inorganic nitride film, an inorganic oxynitride film, or a material obtained by stacking any of these films and the like can be used as the insulating films 521 and 518 or the like. For example, a film including any of a silicon oxide film, a silicon nitride film, a silicon oxynitride film, and an aluminum oxide film, and the like, or a film including a layered material obtained by stacking any of these films can be used for the insulating films 521 and 518, or the like.

Specifically, polyester, polyolefin, polyamide, polyimide, polycarbonate, polysiloxane, an acrylic resin, or the like, or a layered or composite material including resins selected from these, or the like can be used for the insulating films 521 and 518, or the like. Alternatively, a photosensitive material may be used.

Thus, steps due to various components overlapping with the insulating films 521 and 518, for example, can be reduced.

### <<Insulating Film 528>>

For example, any of the materials that can be used for the insulating film 521 can be used for an insulating film 528 or the like. Specifically, a 1-μm-thick polyimide-containing film can be used as the insulating film 528.

### <<Insulating Film 501A>>

For example, any of the materials that can be used for the insulating film 521 can be used for an insulating film 501A. For example, a material having a function of supplying hydrogen can be used for the insulating film 501A.

Specifically, a material in which a material containing silicon and oxygen and a material containing silicon and nitrogen are stacked can be used for the insulating film 501A. For example, a material having a function of releasing hydrogen by heating or the like to supply the hydrogen to another component can be used for the insulating film 501A. Specifically, a material having a function of releasing hydrogen taken in the manufacturing process, by heating or the like, to supply the hydrogen to another component can be used for the insulating film 501A.

For example, a film containing silicon and oxygen that is formed by a chemical vapor deposition method using silane or the like as a source gas can be used as the insulating film 501A.

Specifically, a material in which a 200- to 600-nm-thick material containing silicon and oxygen and a material containing silicon and nitrogen with a thickness of approximately 200 nm are stacked can be used for the insulating film 501A.

### <<Insulating Film 501C>>

For example, any of the materials that can be used for the insulating film 521 can be used for an insulating film 501C. Specifically, a material containing silicon and oxygen can be used for the insulating film 501C. Thus, diffusion of impurities into the pixel circuit, the second display element, or the like can be inhibited.

For example, a 200-nm-thick film containing silicon, oxygen, and nitrogen can be used as the insulating film 501C.

### <<Intermediate Film 754A, Intermediate Film 754B, Intermediate Film 754C>>

A film with a thickness greater than or equal to 10 nm and less than or equal to 500 nm, preferably greater than or equal to 10 nm and less than or equal to 100 nm, can be used for the intermediate film 754A, the intermediate film 754B, or the intermediate film 754C, for example. Note that in this specification, the intermediate film 754A, the intermediate film 754B, or the intermediate film 754C is referred to as an intermediate film.

For example, a material having a function of allowing the passage of hydrogen or the supply of hydrogen can be used for the intermediate film.

For example, a conductive material can be used for the intermediate film.

For example, a light-transmitting material can be used for the intermediate film.

Specifically, a material containing indium and oxygen, a material containing indium, gallium, zinc, and oxygen, a material containing indium, tin, and oxygen, or the like can be used for the intermediate film. Note that the above material is permeable to hydrogen.

Specifically, a 50- or 100-nm-thick film containing indium, gallium, zinc, and oxygen can be used as the intermediate film.

Note that a material in which films serving as etching stoppers are stacked can be used for the intermediate film. Specifically, a material in which a 50-nm-thick film containing indium, gallium, zinc, and oxygen and a 20-nm-thick film containing indium, tin, and oxygen, are stacked in this order can be used for the intermediate film.

### <<Wiring, Terminal, and Conductive Film>>

A conductive material can be used for the wiring or the like. Specifically, a conductive material can be used for the signal line S1(j), the signal line S2(j), the scan line G1(i), the scan line G2(i), the wiring CSCOM, the wiring ANO, the conductive film 511B, the conductive film 511C, or the like.

For example, an inorganic conductive material, an organic conductive material, a metal, conductive ceramics, or the like can be used for the wiring or the like.

Specifically, a metal element selected from aluminum, gold, platinum, silver, copper, chromium, tantalum, titanium, molybdenum, tungsten, nickel, iron, cobalt, palladium, and manganese, or the like can be used for the wiring or the like. Alternatively, an alloy including any of the above-described metal elements, or the like can be used for the wiring or the like. In particular, an alloy of copper and manganese is suitably used in microfabrication with the use of a wet etching method.

Specifically, any of the following structures can be used for the wiring or the like: a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, and the like.

Specifically, a conductive oxide, such as indium oxide, indium tin oxide, indium zinc oxide, zinc oxide, or zinc oxide to which gallium is added, can be used for the wiring or the like.

Specifically, a film containing graphene or graphite can be used for the wiring or the like.

For example, a film including graphene oxide is formed and is subjected to reduction, so that a film including graphene can be formed. As a reducing method, a method with application of heat, a method using a reducing agent, or the like can be employed.

A film containing a metal nanowire can be used for the wiring or the like, for example. Specifically, a nanowire containing silver can be used.

Specifically, a conductive high molecular compound can be used for the wiring or the like.

Note that the terminal 519B can be electrically connected to a flexible printed circuit FPC1 using a conductive material ACF1, for example.

<<Reflective Element 10a(i, j)>>

The reflective element 10a(i, j) is a display element having a function of controlling reflection of light. For example, a liquid crystal element, an electrophoretic element, a display element using MEMS, or the like can be used. Specifically, a reflective liquid crystal display element can be used as the reflective element 10a(i, j). The use of a reflective display element can reduce power consumption of a display panel.

For example, a liquid crystal element driven in any of the following driving modes can be used: an in-plane switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, and the like.

In addition, a liquid crystal element that can be driven by, for example, a vertical alignment (VA) mode such as a multi-domain vertical alignment (MVA) mode, a patterned vertical alignment (PVA) mode, an electrically controlled birefringence (ECB) mode, a continuous pinwheel alignment (CPA) mode, or an advanced super view (ASV) mode can be used.

The reflective element 10a(i, j) includes an electrode 751(i, j), an electrode 752, and a layer 753 containing a liquid crystal material. The layer 753 contains a liquid crystal material whose alignment is controlled by a voltage applied between the electrode 751(i, j) and the electrode 752. For example, the alignment of the liquid crystal material can be controlled by an electric field in the thickness direction (also referred to as the vertical direction) of the layer 753 or the direction that crosses the vertical direction (the horizontal direction, or the diagonal direction).

For example, thermotropic liquid crystal, low-molecular liquid crystal, high-molecular liquid crystal, polymer dispersed liquid crystal, ferroelectric liquid crystal, anti-ferroelectric liquid crystal, or the like can be used for the layer 753. Alternatively, a liquid crystal material which exhibits a cholesteric phase, a smectic phase, a cubic phase, a chiral nematic phase, an isotropic phase, or the like can be used. Alternatively, a liquid crystal material which exhibits a blue phase can be used.

For example, the material that is used for the wiring or the like can be used for the electrode 751(i, j). Specifically, a reflective film can be used for the electrode 751(i, j). For example, a material in which a light-transmitting conductive film and a reflective film having an opening are stacked can be used for the electrode 751(i, j).

For example, a conductive material can be used for the electrode 752. For example, a material having a visible-light-transmitting property can be used for the electrode 752.

For example, a conductive oxide, a metal film thin enough to transmit light, or a metal nanowire can be used for the electrode 752.

Specifically, a conductive oxide containing indium can be used for the electrode 752. Alternatively, a metal thin film with a thickness greater than or equal to 1 nm and less than or equal to 10 nm can be used for the electrode 752. Alternatively, a metal nanowire containing silver can be used for the electrode 752.

Specifically, indium oxide, indium tin oxide, indium zinc oxide, zinc oxide, zinc oxide to which gallium is added, zinc oxide to which aluminum is added, or the like can be used for the electrode 752.

### <<Reflective Film>>

For example, a material that reflects visible light can be used for the reflective film. Specifically, a material containing silver can be used for the reflective film. For example, a material containing silver, palladium, and the like or a material containing silver, copper, and the like can be used for the reflective film.

The reflective film reflects light that passes through the layer 753, for example. This allows the reflective element 10a(i, j) to serve as a reflective display element. Alternatively, for example, a material with unevenness on its surface can be used for the reflective film. In that case, incident light can be reflected in various directions so that a white image can be displayed.

For example, the electrode 751(i, j) or the like can be used as the reflective film.

For example, the reflective film can be provided as a film that includes a region sandwiched between the layer 753 and the electrode 751(i, j). In the case where the electrode 751(i, j) has a light-transmitting property, the reflective film can be provided as a film that includes a region overlapping with the layer 753 with the electrode 751(i, j) positioned between the film and the layer 753.

The reflective film preferably has a shape, for example, including a region that does not block light emitted from the light-emitting element 10b(i, j). The reflective film preferably has a shape with one or more openings 751H, for example.

The opening may have a polygonal shape, a quadrangular shape, an elliptical shape, a circular shape, a cross-like shape, or the like. The opening 751H may also have a stripe shape, a slit-like shape, or a checkered pattern.

If the ratio of the total area of the opening 751H to the total area except for the openings is too high, display performed using the reflective element 10a(i, j) is dark.

If the ratio of the total area of the opening 751H to the total area except for the openings is too low, display performed using the light-emitting element 10b(i, j) is dark.

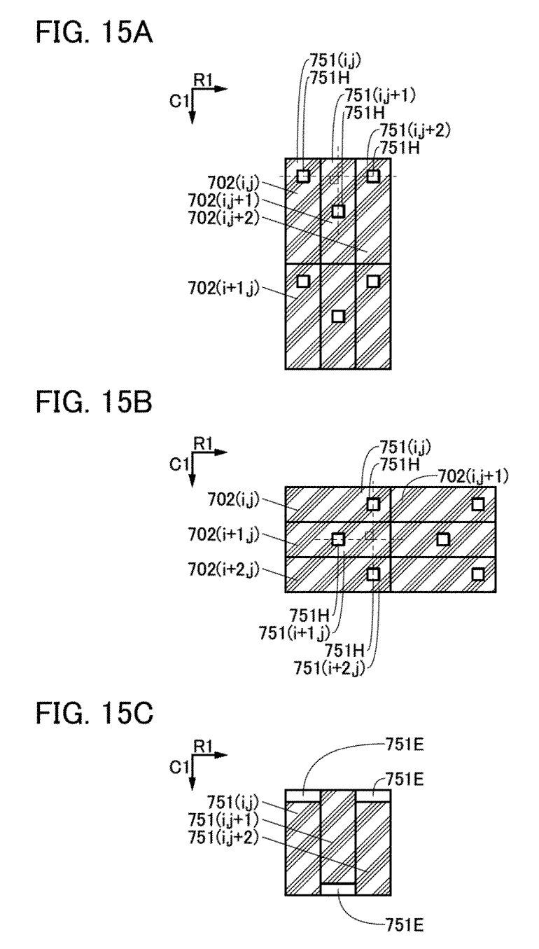

FIGS. 15A to 15C are schematic views each illustrating the shape of a reflective film that can be used in a pixel of the display unit 110.

The opening 751H of the pixel 702(i, j+1), which is adjacent to the pixel 702(i, j), is not provided on a line that extends in the row direction (the direction indicated by the arrow R1 in the drawing) through the opening 751H of the pixel 702(i, j) (see FIG. 15A). Alternatively, for example, the opening 751H of the pixel 702(i+1, j), which is adjacent to the pixel 702(i, j), is not provided on a line that extends in the column direction (the direction indicated by the arrow C1 in the drawing) through the opening 751H of the pixel 702(1, j) (see FIG. 15B).

For example, the opening 751H of the pixel 702(i, j+2) is provided on a line that extends in the row direction through the opening 751H of the pixel 702(i, j) (see FIG. 15A). In addition, the opening 751H of the pixel 702(i, j+1) is provided on a line that is perpendicular to the above-mentioned line between the opening 751H of the pixel 702(i, j) and the opening 751H of the pixel 702(i, j+2).

Alternatively, for example, the opening 751H of the pixel 702(i+2, j) is provided on a line that extends in the column direction through the opening 751H of the pixel 702(i, j) (see FIG. 15B). In addition, for example, the opening 751H of the pixel 702(i+1, j) is provided on a line that is perpendicular to the above-mentioned line between the opening 751H of the pixel 702(i, j) and the opening 751H of the pixel 702(i+2, j).

Thus, a second display element that includes a region overlapping with an opening of a pixel adjacent to one pixel can be apart from a second display element that includes a region overlapping with an opening of the one pixel. A display element which displays color different from that displayed from the second display element of one pixel can be provided as the second display element of another pixel adjacent to the one pixel. The difficulty in arranging a plurality of display elements displaying different colors adjacent to each other can be lowered.

For example, the reflective film can be formed using a material having a shape in which an end portion is cut off so as to form a region 751E that does not block light emitted from the light-emitting element 10b(i, j) (see FIG. 15C). Specifically, the electrode 751(i, j) whose end portion is cut off so as to be shorter in the column direction (the direction indicated by the arrow C1 in the drawing) can be used as the reflective film.

### <<Alignment Films AF1 and AF2>>

Alignment films AF1 and AF2 can be formed using a material containing polyimide or the like, for example. Specifically, a material formed by rubbing treatment or an optical alignment technique such that a liquid crystal material has a predetermined alignment can be used.

For example, a film containing soluble polyimide can be used for the alignment films AF1 and AF2. In this case, the temperature required in forming the alignment films AF1 and AF2 can be low. Accordingly, damage to other components at the time of forming the alignment films AF1 and AF2 can be suppressed.

### <<Coloring Films CF1 and CF2>>

A material transmitting light of a predetermined color can be used for coloring films CF1 and CF2. Thus, the coloring films CF1 and CF2 can be used as a color filter, for example. For example, a material that transmits blue light, green light, or red light can be used for the coloring films CF1 and CF2. Furthermore, a material that transmits yellow light, white light, or the like can be used for the coloring films CF1 and CF2.

Note that a material having a function of converting the emitted light to a predetermined color light can be used for the coloring film CF2. Specifically, quantum dots can be used for the coloring film CF2. Thus, display with high color purity can be achieved.

### <<Light-Blocking Film BM>>

The light-blocking film BM can be formed with a material that prevents light transmission and can thus be used as a black matrix, for example.

### <<Insulating Film 771>>

The insulating film 771 can be formed of polyimide, epoxy resin, acrylic resin, or the like.

### <<Functional Films 770P and 770D>>

An anti-reflection film, a polarizing film, a retardation film, a light diffusion film, a condensing film, or the like can be used for the functional film 770P or the functional film 770D, for example.

Specifically, a film containing a dichromatic pigment can be used for the functional film 770P or the functional film 770D. Alternatively, a material with a columnar structure having an axis along the direction intersecting a surface of a base can be used for the functional film 770P or the functional film 770D. In that case, light can be transmitted in the direction along the axis and scattered in other directions easily.

Alternatively, an antistatic film preventing the attachment of a foreign substance, a water repellent film suppressing the attachment of stain, a hard coat film suppressing a scratch in use, or the like can be used as the functional film 770P.

Specifically, a circularly polarizing film can be used for the functional film 770P. Furthermore, a light diffusion film can be used for the functional film 770D.

<<Light-Emitting Element 10b(i, j)>>

For example, an organic EL element, an inorganic EL element, a light-emitting diode, or the like can be used as the light-emitting element 150b (i, j).

The light-emitting element 10b(i, j) includes an electrode 551(i, j), an electrode 552, and a layer 553(j) containing a light-emitting material.

For example, a light-emitting organic compound can be used for the layer 553(j).

For example, quantum dots can be used for the layer 553(j). Accordingly, the half width becomes narrow, and light of a bright color can be emitted.

For example, a layered material for emitting blue light, green light, or red light, or the like can be used for the layer 553(j).

For example, a belt-like layered material that extends in the column direction along the signal line S2(j) can be used for the layer 553(j).

Alternatively, a layered material for emitting white light can be used for the layer 553(j). Specifically, a layered material in which a layer containing a light-emitting material including a fluorescent material that emits blue light, and a layer containing materials that are other than a fluorescent material and that emit green light and/or red light or a layer containing a material that is other than a fluorescent material and that emits yellow light are stacked can be used for the layer 553(j).

For example, a material that can be used for the wiring or the like can be used for the electrode 551(i,j).

For example, a material that transmits visible light selected from materials that can be used for the wiring or the like can be used for the electrode 551(i, j).

Specifically, conductive oxide, indium-containing conductive oxide, indium oxide, indium tin oxide, indium zinc oxide, zinc oxide, zinc oxide to which gallium is added, or the like can be used for the electrode 551(i, j). Alternatively, a metal film that is thin enough to transmit light can be used as the electrode 551(i, j). Further alternatively, a metal film that transmits part of light and reflects another part of light can be used as the electrode 551(i, j). Thus, the light-emitting element 10b(i, j) can be provided with a microcavity structure. As a result, light of a predetermined wavelength can be extracted more efficiently than light of other wavelengths.

For example, a material that can be used for the wiring or the like can be used for the electrode 552. Specifically, a material that reflects visible light can be used for the electrode 552.

### <<Gate Driver GD>>

Any of a variety of sequential circuits, such as a shift register, can be used as the gate driver GD. For example, a transistor MD, a capacitor, and the like can be used in the gate driver GD. Specifically, a transistor including a semiconductor film that can be formed in the same process as the semiconductor film of the transistor M or the transistor which can be used as the switch SW1 can be used.

As the transistor MD, a transistor having a different structure from the transistor that can be used as the switch SW1 can be used, for example. Specifically, a transistor including the conductive film 524 can be used as the transistor MD.

Note that the transistor MD can have the same structure as the transistor M.

### <<Transistor>>

For example, semiconductor films formed at the same step can be used for transistors in the gate driver, the source driver, and the pixel circuit.

For example, a bottom-gate transistor, a top-gate transistor, or the like can be used for transistors in the gate driver, the source driver, or a pixel circuit.

For example, the OS transistor described in Embodiment 1 can be used. In that case, the above-mentioned idling stop can be performed.

For example, a transistor including an oxide semiconductor film 508, a conductive film 504, a conductive film 512A, and a conductive film 512B can be used as the switch SW1 (see FIG. 14B). Note that an insulating film 506 includes a region sandwiched between the oxide semiconductor film 508 and the conductive film 504.

The conductive film 504 includes a region overlapping with the oxide semiconductor film 508. The conductive film 504 functions as a gate electrode. The insulating film 506 functions as a gate insulating film.

The conductive film 512A and the conductive film 512B are electrically connected to the oxide semiconductor film 508. The conductive film 512A has one of a function as a source electrode and a function as a drain electrode, and the conductive film 512B has the other.

A transistor including the conductive film 524 can be used as the transistor in the gate driver, the source driver, or the pixel circuit. The conductive film 524 includes a region so that the oxide semiconductor film 508 is sandwiched between the conductive film 504 and the region. Note that the insulating film 516 includes a region sandwiched between the conductive film 524 and the oxide semiconductor film 508. For example, the conductive film 524 is electrically connected to a wiring supplying the same potential as that supplied to the conductive film 504.

A conductive film in which a 10-nm-thick film containing tantalum and nitrogen and a 300-nm-thick film containing copper are stacked can be used as the conductive film 504, for example. A film containing copper includes a region provided so that a film containing tantalum and nitrogen is positioned between the film containing copper and the insulating film 506.

A material in which a 400-nm-thick film containing silicon and nitrogen and a 200-nm-thick film containing silicon, oxygen, and nitrogen are stacked can be used for the insulating film 506, for example. Note that the film containing silicon and nitrogen includes a region so that the film containing silicon, oxygen, and nitrogen is sandwiched between the region and the oxide semiconductor film 508.

A 25-nm-thick film containing indium, gallium, and zinc can be used as the oxide semiconductor film 508, for example.

For example, a conductive film in which a 50-nm-thick film containing tungsten, a 400-nm-thick film containing aluminum, and a 100-nm-thick film containing titanium are stacked in this order can be used as the conductive film 512A or 512B. Note that the film containing tungsten includes a region in contact with the oxide semiconductor film 508.

Note that this embodiment can be combined with any of the other embodiments in this specification as appropriate.

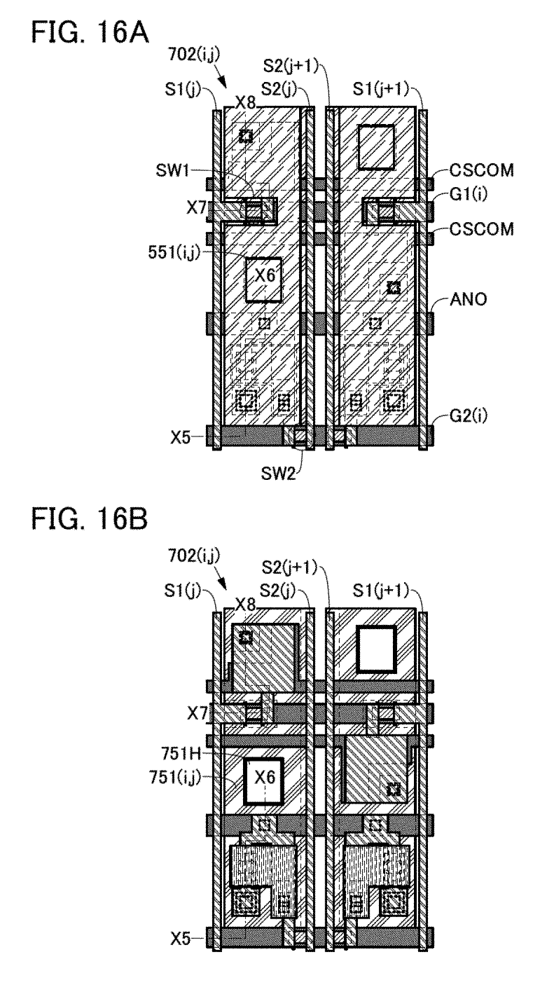

FIG. 16A is a bottom view illustrating part of the pixel of the display panel in FIG. 12B. FIG. 16B is a bottom view illustrating part of the structure in FIG. 16A in which some components are omitted.

### Embodiment 3

A display device described in this embodiment includes the display unit described in the above embodiments and a touch sensor unit.

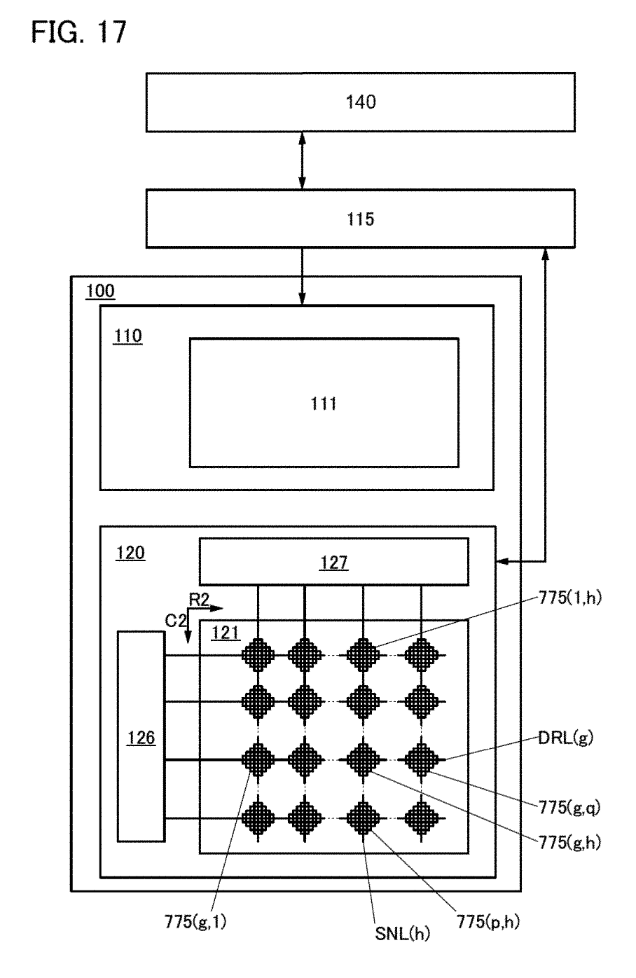

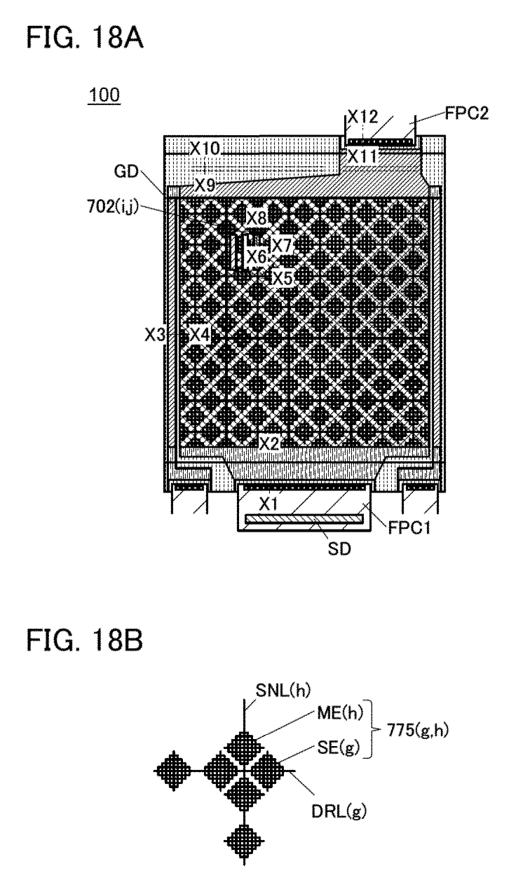

FIG. 17 is a block diagram showing the structure of the display device 100 including the touch sensor unit 120 and the display unit 110. FIG. 18A is a top view of the display device 100. FIG. 18B is a schematic view showing part of an input portion of the display device 100.

The touch sensor unit 120 includes the sensor array 121, the TS driver 126, and the sensing circuit 127 (see FIG. 17).

The sensor array 121 includes a region overlapping with the pixel array 111 of the display unit 110. The sensor array 121 is configured to sense an object approaching the region overlapping with the pixel array 111.

The sensor array 121 includes a group consisting of sensing elements 775(g,1) to 775(g, q) and another group consisting of sensing elements 775(1, h) to 775(p, h). Note that g is an integer greater than or equal to 1 and less than or equal to p, h is an integer greater than or equal to 1 and less than or equal to q, and each of p and q is an integer greater than or equal to 1.

The one group of the sensing elements 775(g, 1) to 775(g, q) include the sensing element 775(g, h). The sensing elements 775(g, 1) to 775(g, q) are arranged in a row direction (indicated by the arrow R2 in the drawing).

The another group of sensing elements 775(1, h) to 775(p, h) include the sensing element 775(g, h) and are provided in the column direction (the direction indicated by the arrow C2 in the drawing) that intersects the row direction.

The one group of sensing elements 775(g, 1) to 775(g, q) provided in the row direction include an electrode SE(g) that is electrically connected to a control line DRL(g) (see FIG. 18B).

The another group of sensor elements 775(1, h) to 775(p, h) provided in the column direction include an electrode ME(h) that is electrically connected to a sensor signal line SNL(h) (see FIG. 18B).

The electrode SE(g) and the electrode ME(h) preferably have a light-transmitting property.

The wiring DRL(g) is configured to supply a control signal.

The wiring SNL(h) is configured to receive a sensor signal.

The electrode ME(h) is provided so that an electric field can be formed between the electrode ME(h) and the electrode SE(g). When an object such as a finger approaches the sensor array 121, the electric field is blocked, and the sensing element 775(g, h) supplies the sensor signal.

The TS driver 126 is electrically connected to the wiring DRL(g) and is configured to supply the control signal. For example, a rectangular wave, a sawtooth wave, a triangular wave, or the like can be used as the control signal.

The sensing circuit 127 is electrically connected to the wiring SNL(h) and is configured to supply the sensor signal on the basis of change in the potential of the wiring SNL(h). Note that the sensor signal includes, for example, positional data.

The sensor signal is supplied to the controller IC 115. The controller IC 115 supplies data corresponding to the sensor signal to the host 140 to update the image displayed with the pixel array 111.

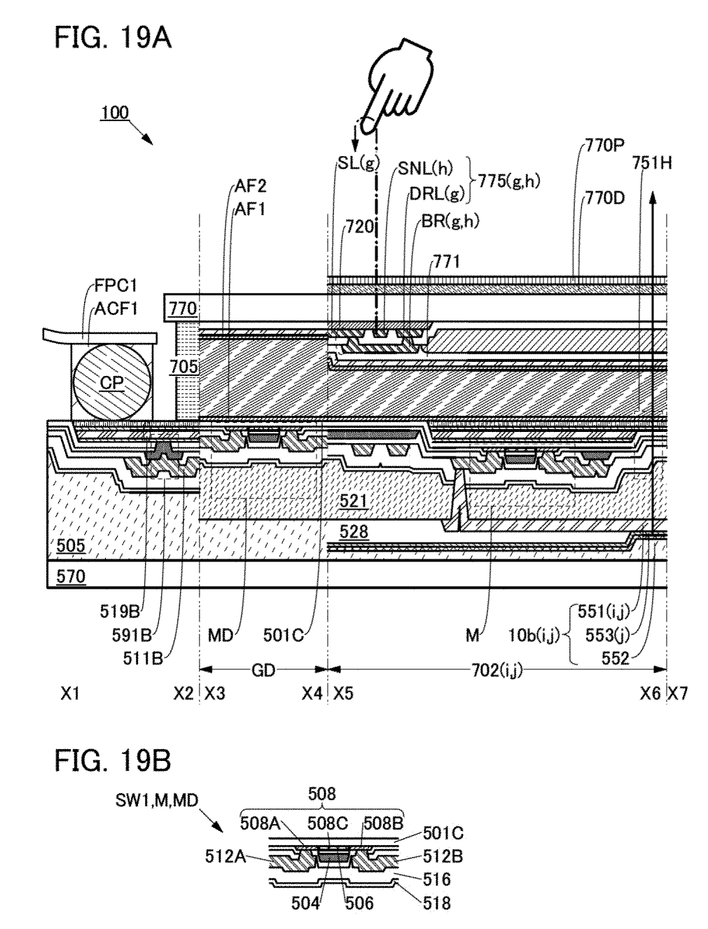

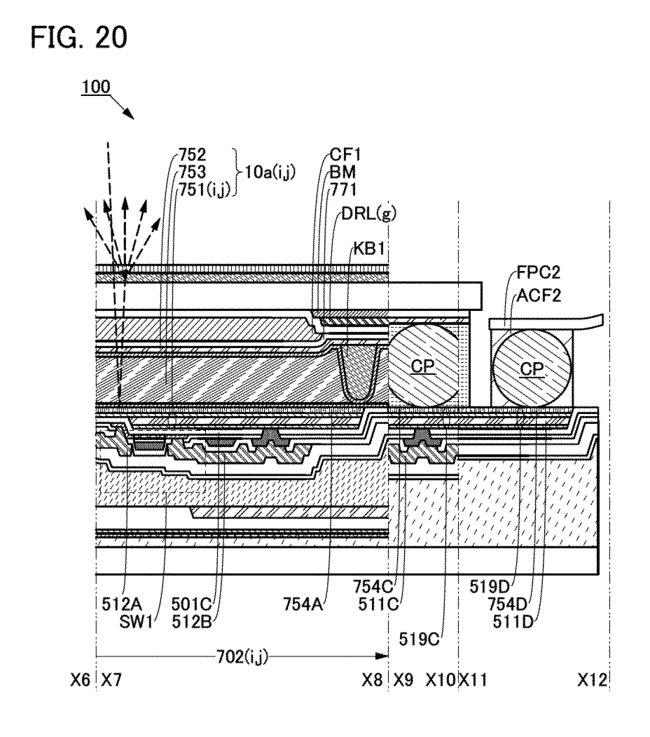

FIGS. 19A and 19B and FIG. 20 illustrate the structure of the display device 100. FIG. 19A is a cross-sectional view taken along lines X1-X2, X3-X4, and X5-X6 in FIG. 18A. FIG. 19B is a cross-sectional view illustrating part of the structure illustrated in FIG. 19A.

FIG. 20 is a cross-sectional view taken along lines X7-X8, X9-X10, and X11-X12 in FIG. 18A.

The display device 100 is different from, for example, the display unit 110 in Embodiment 2 in including a functional layer 720 and a top-gate transistor. Different structures will be described in detail below, and the above description is referred to for the other similar structures.

The functional layer 720 includes a region surrounded by the substrate 770, the insulating film 501C, and the sealant 705 (FIGS. 19A and 19B).

The functional layer 720 includes the wiring DRL(g), the wiring SNL(h), and the sensing element 775(g, h).

The gap between the wiring DRL(g) and the electrode 752 or between the wiring SNL(h) and the electrode 752 is greater than or equal to 0.2 μm and less than or equal to 16 μm, preferably greater than or equal to 1 μm and less than or equal to 8 μm, and further preferably greater than or equal to 2.5 μm and less than or equal to 4 μm.

The display device 100 includes a conductive film 511D (see FIG. 20).

Note that a conductive material CP or the like can be provided between the wiring DRL(g) and the conductive film 511D to electrically connect the wiring DRL(g) and the conductive film 511D. Alternatively, the conductive material CP or the like can be provided between the wiring SNL(h) and the conductive film 511D to electrically connect the wiring SNL(h) and the conductive film 511D. A material that can be used for the wiring or the like can be used for the conductive film 511D, for example.

The display device 100 includes a terminal 519D (see FIG. 20).

The terminal 519D is provided with the conductive film 511D and an intermediate film 754D, and the intermediate film 754D includes a region in contact with the conductive film 511D.

For example, a material that can be used for a wiring or the like can be used for the terminal 519D. Specifically, the terminal 519D can have the same structure as that of the terminal 519B or the terminal 519C.

Note that for example, the terminal 519D can be electrically connected to a flexible printed circuit FPC2 using a conductive material ACF2, for example. Thus, a control signal can be supplied to the wiring DRL(g) with the use of the terminal 519D, for example. Alternatively, a sensor signal can be supplied from the wiring SNL(h) with the use of the terminal 519D.

A transistor that can be used as the switch SW1, the transistor M, and the transistor MD each include the conductive film 504 having a region overlapping with the insulating film 501C and the oxide semiconductor film 508 having a region sandwiched between the insulating film 501C and the conductive film 504. Note that the conductive film 504 functions as a gate electrode (see FIG. 19B).

The oxide semiconductor film 508 includes a first region 508A, a second region 508B, and a third region 508C. The first region 508A and the second region 508B do not overlap with the conductive film 504. The third region 508C is positioned between the first region 508A and the second region 508B and overlaps with the conductive film 504.

The transistor MD includes the insulating film 506 between the third region 508C and the conductive film 504. Note that the insulating film 506 functions as a gate insulating film.

The first region 508A and the second region 508B have a lower resistivity than the third region 508C, and function as a source region and a drain region.

For example, an oxide semiconductor film is subjected to plasma treatment using a gas including a rare gas, so that the first region 508A and the second region 508B can be formed in the oxide semiconductor film 508.

For example, the conductive film 504 can be used as a mask. The use of the conductive film 504 as a mask allows the shape of part of the third region 508C to be self-aligned with the shape of an end of the conductive film 504.

The transistor MD includes the conductive film 512A and the conductive film 512B that are in contact with the first region 508A and the second region 508B, respectively. The conductive film 512A and the conductive film 512B function as a source electrode and a drain electrode.

A transistor that can be formed in the same process as the transistor MD can be used as the transistor M, for example.

### Embodiment 4

In this embodiment, electronic devices that include a display device of one embodiment of the present invention will be described.

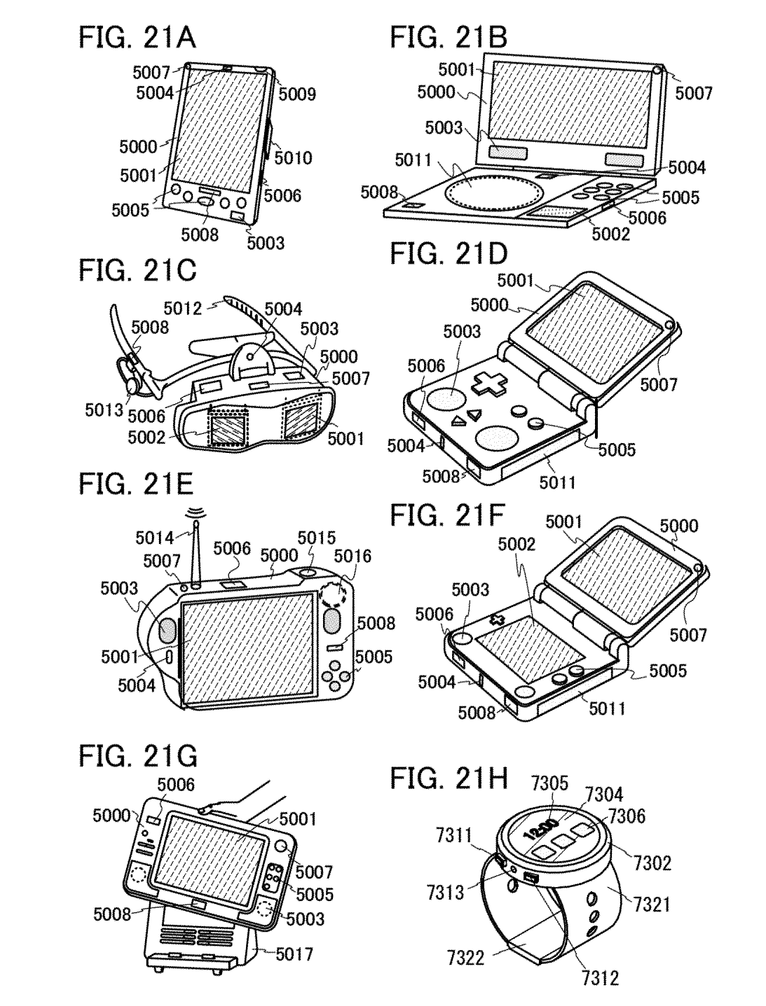

The display device can display an image by combining display with a reflective element and display with a light-emitting element as appropriate, and thus can display images with high quality, regardless of the weather (fine, rainy, or cloudy weather), the time (day or night), or the like. The display device is therefore suited for a display portion of a portable electronic device used at various places. The display device enables both smooth display of moving image and low power consumption, and thus can increase the operating time of a portable electronic device that has a battery as its power source. Of course, the display device can be applied to display portions of various electronic devices other than portable electronic devices. Here, some of the examples of the electronic devices including a display portion will be explained with reference to FIGS. 21A to 21H.

FIGS. 21A to 21G illustrate electronic devices. These electronic devices can include a housing 5000, a display portion 5001, a speaker 5003, an LED lamp 5004, operation keys 5005 (including a power switch and an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, and the like.

FIG. 21A illustrates a mobile computer that can include a switch 5009, an infrared port 5010, and the like in addition to the above components. FIG. 21B illustrates a portable image reproducing device (e.g., a DVD reproducing device) provided with a memory medium, and the image reproducing device can include a second display portion 5002, a memory medium reading portion 5011, and the like in addition to the above components. FIG. 21C illustrates a goggle-type display that can include a second display portion 5002, a support portion 5012, an earphone 5013, and the like in addition to the above components. FIG. 21D illustrates a portable game machine that can include a memory medium reading portion 5011 and the like in addition to the above components. FIG. 21E illustrates a digital camera having a television reception function, and the digital camera can include an antenna 5014, a shutter button 5015, an image receiving portion 5016, and the like in addition to the above objects. FIG. 21F illustrates a portable game machine that can include a second display portion 5002, a memory medium reading portion 5011, and the like in addition to the above components. FIG. 21G illustrates a portable television receiver, which can include a charger 5017 capable of transmitting and receiving signals, and the like in addition to the above components.

The electronic appliances illustrated in FIGS. 21A to 21G can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion. Furthermore, the electronic device including a plurality of display portions can have a function of displaying image information mainly on one display portion while displaying text information on another display portion, a function of displaying a three-dimensional image by displaying images where parallax is considered on a plurality of display portions, or the like. Furthermore, the electronic device including an image receiving portion can have a function of photographing a still image, a function of photographing a moving image, a function of automatically or manually correcting a photographed image, a function of storing a photographed image in a memory medium (an external memory medium or a memory medium incorporated in the camera), a function of displaying a photographed image on the display portion, or the like. Note that functions which can be provided for the electronic devices illustrated in FIGS. 21A to 21G are not limited to those described above, and the electronic devices can have a variety of functions.

FIG. 21H illustrates a smart watch, which includes a housing 7302, a display panel 7304, operation buttons 7311 and 7312, a connection terminal 7313, a band 7321, a clasp 7322, and the like.

The display panel 7304 mounted in the housing 7302 serving as a bezel includes a non-rectangular display region. The display panel 7304 may have a rectangular display region. The display panel 7304 can display an icon 7305 indicating time, another icon 7306, and the like.

The smart watch in FIG. 21H can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion.

The housing 7302 can include a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like. Note that the smart watch can be manufactured using the light-emitting element for the display panel 7304.

### Embodiment 5

### <Composition of CAC-OS>

In this embodiment, described is the composition of a cloud-aligned composite oxide semiconductor (CAC-OS) applicable to an oxide-semiconductor transistor disclosed in one embodiment of the present invention.

The CAC-OS has, for example, a composition in which elements included in an oxide semiconductor are unevenly distributed. Materials including unevenly distributed elements each have a size of greater than or equal to 0.5 nm and less than or equal to 10 nm, preferably greater than or equal to 1 nm and less than or equal to 2 nm, or a similar size. Note that in the following description of an oxide semiconductor, a state in which one or more metal elements are unevenly distributed and regions including the metal element(s) are mixed is referred to as a mosaic pattern or a patch-like pattern. The region has a size of greater than or equal to 0.5 nm and less than or equal to 10 nm, preferably greater than or equal to 1 nm and less than or equal to 2 nm, or a similar size.

Note that an oxide semiconductor preferably contains at least indium. In particular, indium and zinc are preferably contained. In addition, aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, of the CAC-OS, an In—Ga—Zn oxide with the CAC composition (such an In—Ga—Zn oxide may be particularly referred to as CAC-IGZO) has a composition in which materials are separated into indium oxide (InO_{X1}, where X1 is a real number greater than 0) or indium zinc oxide (In_{X2}Zn_{Y2}O_{Z2}, where X2, Y2, and Z2 are real numbers greater than 0), and gallium oxide (GaO_{X3}, where X3 is a real number greater than 0) or gallium zinc oxide (Ga_{X4}Zn_{Y4}O_{Z4}, where X4, Y4, and Z4 are real numbers greater than 0), and a mosaic pattern is formed. Then, InO_{X1} or In_{X2}Zn_{Y2}O_{Z2} forming the mosaic pattern is evenly distributed in the film. This composition is also referred to as a cloud-like composition.

That is, the CAC-OS is a composite oxide semiconductor with a composition in which a region including GaO_{X3} as a main component and a region including In_{X2}Zn_{Y2}O_{Z2} or InO_{X1} as a main component are mixed. Note that in this specification, for example, when the atomic ratio of In to an element Min a first region is greater than the atomic ratio of In to an element M in a second region, the first region has higher In concentration than the second region.

Note that a compound including In, Ga, Zn, and O is also known as IGZO.

Typical examples of IGZO include a crystalline compound represented by InGaO₃(ZnO)ₘ₁ (m1 is a natural number) and a crystalline compound represented by In(₁₊ₓ₀)Ga(₁₋ₓ₀)O₃(ZnO)ₘ₀ (−1≦x0≦1; m0 is a given number).

The above crystalline compounds have a single crystal structure, a polycrystalline structure, or a c-axis-aligned crystalline (CAAC) structure. Note that the CAAC structure is a crystal structure in which a plurality of IGZO nanocrystals have c-axis alignment and are connected in the a-b plane direction without alignment.

On the other hand, the CAC-OS relates to the material composition of an oxide semiconductor. In a material composition of a CAC-OS including In, Ga, Zn, and O, nanoparticle regions including Ga as a main component are observed in part of the CAC-OS and nanoparticle regions including In as a main component are observed in part thereof. These nanoparticle regions are randomly dispersed to form a mosaic pattern. Therefore, the crystal structure is a secondary element for the CAC-OS.

Note that in the CAC-OS, a stacked-layer structure including two or more films with different atomic ratios is not included. For example, a two-layer structure of a film including In as a main component and a film including Ga as a main component is not included.

A boundary between the region including GaO_{X3} as a main component and the region including In_{X2}Zn_{Y2}O_{Z2} or InO_{X1} as a main component is not clearly observed in some cases.

In the case where one or more of aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium in a CAC-OS, nanoparticle regions including the selected metal element(s) as a main component(s) are observed in part of the CAC-OS and nanoparticle regions including In as a main component are observed in part thereof, and these nanoparticle regions are randomly dispersed to form a mosaic pattern in the CAC-OS.

The CAC-OS can be formed by a sputtering method under conditions where a substrate is not heated intentionally, for example. In the case of forming the CAC-OS by a sputtering method, one or more selected from an inert gas (typically, argon), an oxygen gas, and a nitrogen gas may be used as a deposition gas. The ratio of the flow rate of an oxygen gas to the total flow rate of the deposition gas at the time of deposition is preferably as low as possible, and for example, the flow ratio of an oxygen gas is preferably higher than or equal to 0% and less than 30%, further preferably higher than or equal to 0% and less than or equal to 10%.

The CAC-OS is characterized in that no clear peak is observed in measurement using θ/2θ scan by an out-of-plane method, which is an X-ray diffraction (XRD) measurement method. That is, X-ray diffraction shows no alignment in the a-b plane direction and the c-axis direction in a measured region.

In the CAC-OS, an electron diffraction pattern that is obtained by irradiation with an electron beam with a probe diameter of 1 nm (also referred to as nanobeam electron beam) has regions with high luminance in a ring pattern and a plurality of bright spots appear in the ring-like pattern. Therefore, the electron diffraction pattern indicates that the crystal structure of the CAC-OS includes a nanocrystal (nc) structure with no alignment in plan-view and cross-sectional directions.

For example, an energy dispersive X-ray spectroscopy (EDX) mapping image confirms that an In—Ga—Zn oxide with the CAC composition has a structure in which a region including GaO_{X3} as a main component and a region including In_{X2}Zn_{Y2}O_{Z2} or InO_{X1} as a main component are unevenly distributed and mixed.

The CAC-OS has a structure different from that of an IGZO compound in which metal elements are evenly distributed, and has characteristics different from those of the IGZO compound. That is, in the CAC-OS, regions including GaO_{X3} or the like as a main component and regions including In_{X2}Zn_{Y2}O_{Z2} or InO_{X1} as a main component are separated to form a mosaic pattern.

The conductivity of a region including In_{X2}Zn_{Y2}O_{Z2} or InO_{X1} as a main component is higher than that of a region including GaO_{X3} or the like as a main component. In other words, when carriers flow through regions including In_{X2}Zn_{Y2}O_{Z2} or InO_{X1} as a main component, the conductivity of an oxide semiconductor is exhibited. Accordingly, when regions including In_{X2}Zn_{Y2}O_{Z2} or InO_{X1} as a main component are distributed in an oxide semiconductor like a cloud, high field-effect mobility (μ) can be achieved.

In contrast, the insulating property of a region including GaO_{X3} or the like as a main component is higher than that of a region including In_{X2}Zn_{Y2}O_{Z2} or InO_{X1} as a main component. In other words, when regions including GaO_{X3} or the like as a main component are distributed in an oxide semiconductor, leakage current can be suppressed and favorable switching operation can be achieved.

Accordingly, when a CAC-OS is used for a semiconductor element, the insulating property derived from GaO_{X3} or the like and the conductivity derived from In_{X2}Zn_{Y2}O_{Z2} or InO_{X1} complement each other, whereby high on-state current (Ion) and high field-effect mobility (μ) can be achieved.

A semiconductor element including a CAC-OS has high reliability. Thus, the CAC-OS is suitably used in a variety of semiconductor devices typified by a display.

This application is based on Japanese Patent Application Serial No. 2016-120435 filed with Japan Patent Office on Jun. 17, 2016, the entire contents of which are hereby incorporated by reference.

What is claimed is:

1. A semiconductor device comprising:
a first controller;
a register;
a frame memory; and
an image processing portion,
wherein the frame memory is configured to store image data,
wherein the image processing portion is configured to process the image data,
wherein the register is configured to store a parameter for performing processing in the image processing portion,
wherein the frame memory is configured to retain the image data while power supply to the frame memory is stopped,
wherein the register comprises a scan chain register, a first register, and a second register,
wherein the scan chain register is configured to retain the parameter while power supply to the register is stopped,
wherein a transistor in the scan chain register comprises an oxide semiconductor in a channel formation region, and
wherein the first controller is configured to control power supply to the register, power supply to the frame memory, and power supply to the image processing portion.

2. The semiconductor device according to claim 1,
wherein the scan chain register comprises a third register and a fourth register,
wherein an output terminal of the third register is electrically connected to an input terminal of the fourth register,
wherein the first register is configured to read data stored in the third register,
wherein the second register is configured to read data stored in the fourth register, and
wherein the data read by the first register and the data read by the second register are output to the image processing portion as the parameter.

3. The semiconductor device according to claim 1,
wherein the scan chain register comprises a third register and a fourth register,
wherein the first register comprises a first input terminal, a first output terminal, and a second output terminal,
wherein the second register comprises a second input terminal, a third output terminal, and a fourth output terminal,
wherein the third register comprises a third input terminal, a fourth input terminal, and a fifth output terminal,
wherein the fourth register comprises a fifth input terminal, a sixth input terminal, and a sixth output terminal,
wherein the first output terminal of the first register is electrically connected to the image processing portion,
wherein the third output terminal of the second register is electrically connected to the image processing portion,
wherein the first input terminal of the first register is electrically connected to the fifth output terminal of the third register,
wherein the second output terminal of the first register is electrically connected to the fourth input terminal of the third register,
wherein the second input terminal of the second register is electrically connected to the sixth output terminal of the fourth register,
wherein the fourth output terminal of the second register is electrically connected to the sixth input terminal of the fourth register,
wherein the fifth output terminal of the third register is electrically connected to the fifth input terminal of the fourth register,
wherein the first register is configured to store data input to the first input terminal, and
wherein the second register is configured to store data input to the second input terminal.

4. The semiconductor device according to claim 3,
wherein a first clock signal, a second clock signal, a third clock signal, a fourth clock signal, a first potential, and a second potential are input to the register,
wherein the first potential is higher than the second potential,
wherein each of the third register and the fourth register comprises a first transistor, a second transistor, a third transistor, a fourth transistor, a fifth transistor, a sixth transistor, a first capacitor, and a second capacitor,
wherein in each of the third register and the fourth register,
the first potential is input to one of a source and a drain of the first transistor,
the other of the source and the drain of the first transistor is electrically connected to one of a source and a drain of the second transistor,
the other of the source and the drain of the second transistor is electrically connected to one of a source and a drain of the third transistor,
the second potential is input to the other of the source and the drain of the third transistor,
the second clock signal is input to a gate of the second transistor,
the first clock signal is input to a gate of the third transistor,
a first terminal of the first capacitor is electrically connected to the one of the source and the drain of the third transistor,
the second potential is input to a second terminal of the first capacitor,
a gate of the fourth transistor is electrically connected to the first terminal of the first capacitor,
the first potential is input to one of a source and a drain of the fourth transistor,
the other of the source and the drain of the fourth transistor is electrically connected to one of a source and a drain of the fifth transistor,
the other of the source and the drain of the fifth transistor is electrically connected to one of a source and a drain of the sixth transistor,
the second potential is input to the other of the source and the drain of the sixth transistor,
the fourth clock signal is input to a gate of the fifth transistor,
the third clock signal is input to a gate of the sixth transistor,
a first terminal of the second capacitor is electrically connected to the one of the source and the drain of the sixth transistor, and
the second potential is input to a second terminal of the second capacitor,
wherein in the third register, a gate of the first transistor is electrically connected to the third input terminal, the gate of the fourth transistor is electrically connected to the fourth input terminal, and the one of the source and the drain of the sixth transistor is electrically connected to the fifth output terminal, and
wherein in the fourth register, the gate of the first transistor is electrically connected to the fifth input terminal, the gate of the fourth transistor is electrically connected to the sixth input terminal, and the one of the source and the drain of the sixth transistor is electrically connected to the sixth output terminal.

5. The semiconductor device according to claim 3,
wherein a first signal, a second signal, a third signal, a first potential, and a second potential are input to the register,
wherein the first potential is higher than the second potential,
wherein each of the first register and the second register comprises a seventh transistor, an eighth transistor, a ninth transistor, a tenth transistor, an eleventh transistor, a first inverter, and a second inverter,
wherein in each of the first register and the second register,
the first potential is input to one of a source and a drain of the seventh transistor,
the other of the source and the drain of the seventh transistor is electrically connected to one of a source and a drain of the eighth transistor,
the other of the source and the drain of the eighth transistor is electrically connected to one of a source and a drain of the ninth transistor,
the first signal is input to a gate of the eighth transistor,
the second signal is input to a gate of the ninth transistor,
the second potential is input to the other of the source and the drain of the ninth transistor,
an input terminal of the first inverter is electrically connected to an output terminal of the second inverter,
an input terminal of the second inverter is electrically connected to an output terminal of the first inverter,
a gate of the tenth transistor is electrically connected to the one of the source and the drain of the ninth transistor,
the first potential is input to one of a source and a drain of the tenth transistor,
the other of the source and the drain of the tenth transistor is electrically connected to one of a source and a drain of the eleventh transistor, and
the third signal is input to a gate of the eleventh transistor,
wherein in the first register, a gate of the seventh transistor is electrically connected to the first input terminal, the input terminal of the first inverter is electrically connected to the first output terminal, and the other of the source and the drain of the eleventh transistor is electrically connected to the second output terminal, and
wherein in the second register, the gate of the seventh transistor is electrically connected to the second input terminal, the input terminal of the first inverter is electrically connected to the third output terminal, and the other of the source and the drain of the eleventh transistor is electrically connected to the fourth output terminal.

6. The semiconductor device according to claim 3,
wherein a first signal, a second signal, and a third signal are input to the register,
wherein each of the first register and the second register comprises a seventh transistor, an eighth transistor, a ninth transistor, a tenth transistor, an eleventh transistor, a first inverter, and a second inverter,
wherein in each of the first transistor and the second register,
the first potential is input to one of a source and a drain of the seventh transistor,
the other of the source and the drain of the seventh transistor is electrically connected to one of a source and a drain of the eighth transistor,
the other of the source and the drain of the eighth transistor is electrically connected to one of a source and a drain of the ninth transistor,
the first signal is input to a gate of the eighth transistor,
the second signal is input to a gate of the ninth transistor,
the second potential is input to the other of the source and the drain of the ninth transistor,
an input terminal of the first inverter is electrically connected to an output terminal of the second inverter,
an input terminal of the second inverter is electrically connected to an output terminal of the first inverter,
a gate of the tenth transistor is electrically connected to the one of the source and the drain of the ninth transistor,
the first potential is input to one of a source and a drain of the tenth transistor,
the other of the source and the drain of the tenth transistor is electrically connected to one of a source and a drain of the eleventh transistor, and
the third signal is input to a gate of the eleventh transistor,
wherein in the first register, a gate of the seventh transistor is electrically connected to the first input terminal, the input terminal of the first inverter is electrically connected to the first output terminal, and the other of the source and the drain of the eleventh transistor is electrically connected to the second output terminal, and
wherein in the second register, the gate of the seventh transistor is electrically connected to the second input terminal, the input terminal of the first inverter is electrically connected to the third output terminal, and the other of the source and the drain of the eleventh transistor is electrically connected to the fourth output terminal.

7. The semiconductor device according to claim 5,
wherein each of the seventh to the eleventh transistors comprises an oxide semiconductor in a channel formation region.

8. The semiconductor device according to claim 1,
wherein the frame memory comprises a plurality of memory cells,
wherein the plurality of memory cells each comprise a twelfth transistor and a third capacitor,
wherein the twelfth transistor controls charge and discharge of the third capacitor, and
wherein the twelfth transistor comprises an oxide semiconductor in a channel formation region.

9. The semiconductor device according to claim 1, comprising a second controller,
wherein the second controller is configured to generate a timing signal, and
wherein the register is configured to store a parameter for generating the timing signal in the second controller.

10. The semiconductor device according to claim 9,
wherein the first controller is configured to control power supply to the second controller.

11. The semiconductor device according to claim 1, comprising a third controller,
wherein the third controller is configured to receive a fourth signal from an optical sensor and to generate a fifth signal for performing processing in the image processing portion.

12. The semiconductor device according to claim 1,
wherein the semiconductor device is configured to generate a sixth signal for displaying a static image on the basis of the image data stored in the frame memory and of the parameter stored in the register when an image data and a parameter are not input from an external device.

13. The semiconductor device according to claim 1, comprising a source driver,
wherein the source driver is configured to generate a data signal on the basis of an image data processed by the image processing portion.

14. The semiconductor device according to claim 1, comprising a source driver,
wherein the source driver is configured to generate a first data signal or a second data signal on the basis of an image data processed by the image processing portion,
wherein the first data signal makes a reflective element drive, and
wherein the second data signal makes a light-emitting element drive.

15. The semiconductor device according to claim 13,
wherein the first controller is configured to control power supply to the source driver.

16. A semiconductor device comprising:
a controller;
a register;
a frame memory; and
an image processing portion,
wherein the frame memory is configured to store image data,
wherein the image processing portion is configured to process the image data,
wherein the register is configured to store a parameter for performing processing in the image processing portion,
wherein the frame memory is configured to retain the image data while power supply to the frame memory is stopped,
wherein the register comprises a scan chain register, and a first register,
wherein the scan chain register is configured to retain the parameter while power supply to the register is stopped,
wherein a transistor in the scan chain register comprises an oxide semiconductor in a channel formation region, and
wherein the controller is configured to control power supply to the register, power supply to the frame memory, and power supply to the image processing portion.

17. The semiconductor device according to claim 16,
wherein the scan chain register comprises a second register,
wherein the first register is configured to read data stored in the second register, and
wherein the data read by the first register is output to the image processing portion as the parameter.

18. The semiconductor device according to claim 16,
wherein the scan chain register comprises a second register,
wherein the first register comprises a first input terminal, a first output terminal, and a second output terminal,
wherein the second register comprises a second input terminal, a third input terminal, and a third output terminal,
wherein the first output terminal of the first register is electrically connected to the image processing portion,
wherein the first input terminal of the first register is electrically connected to the third output terminal of the second register,
wherein the second output terminal of the first register is electrically connected to the third input terminal of the second register, and
wherein the first register is configured to store data input to the first input terminal.

19. The semiconductor device according to claim 18,
wherein a first clock signal, a second clock signal, a third clock signal, a fourth clock signal, a first potential, and a second potential are input to the register,
wherein the first potential is higher than the second potential,
wherein the second register comprises a first transistor, a second transistor, a third transistor, a fourth transistor, a fifth transistor, a sixth transistor, a first capacitor, and a second capacitor,
wherein in the second register,
the first potential is input to one of a source and a drain of the first transistor,
the other of the source and the drain of the first transistor is electrically connected to one of a source and a drain of the second transistor,
the other of the source and the drain of the second transistor is electrically connected to one of a source and a drain of the third transistor,
the second potential is input to the other of the source and the drain of the third transistor,
the second clock signal is input to a gate of the second transistor,
the first clock signal is input to a gate of the third transistor,
a first terminal of the first capacitor is electrically connected to the one of the source and the drain of the third transistor,
the second potential is input to a second terminal of the first capacitor,
a gate of the fourth transistor is electrically connected to the first terminal of the first capacitor,
the first potential is input to one of a source and a drain of the fourth transistor,
the other of the source and the drain of the fourth transistor is electrically connected to one of a source and a drain of the fifth transistor,
the other of the source and the drain of the fifth transistor is electrically connected to one of a source and a drain of the sixth transistor,
the second potential is input to the other of the source and the drain of the sixth transistor,
the fourth clock signal is input to a gate of the fifth transistor,
the third clock signal is input to a gate of the sixth transistor,
a first terminal of the second capacitor is electrically connected to the one of the source and the drain of the sixth transistor, and
the second potential is input to a second terminal of the second capacitor, and
wherein in the second register, a gate of the first transistor is electrically connected to the second input terminal, the gate of the fourth transistor is electrically connected to the third input terminal, and the one of the source and the drain of the sixth transistor is electrically connected to the third output terminal.

20. The semiconductor device according to claim 18,
wherein a first signal, a second signal, a third signal, a first potential, and a second potential are input to the register,
wherein the first potential is higher than the second potential,
wherein the first register comprises a seventh transistor, an eighth transistor, a ninth transistor, a tenth transistor, an eleventh transistor, a first inverter, and a second inverter,
wherein in the first register,
the first potential is input to one of a source and a drain of the seventh transistor,
the other of the source and the drain of the seventh transistor is electrically connected to one of a source and a drain of the eighth transistor,
the other of the source and the drain of the eighth transistor is electrically connected to one of a source and a drain of the ninth transistor,
the first signal is input to a gate of the eighth transistor,
the second signal is input to a gate of the ninth transistor,
the second potential is input to the other of the source and the drain of the ninth transistor,
an input terminal of the first inverter is electrically connected to an output terminal of the second inverter,
an input terminal of the second inverter is electrically connected to an output terminal of the first inverter,
a gate of the tenth transistor is electrically connected to the one of the source and the drain of the ninth transistor,
the first potential is input to one of a source and a drain of the tenth transistor,
the other of the source and the drain of the tenth transistor is electrically connected to one of a source and a drain of the eleventh transistor, and
the third signal is input to a gate of the eleventh transistor, and
wherein in the first register, a gate of the seventh transistor is electrically connected to the first input terminal, the input terminal of the first inverter is electrically connected to the first output terminal, and the other of the source and the drain of the eleventh transistor is electrically connected to the second output terminal.

21. The semiconductor device according to claim 19,
wherein a first signal, a second signal, and a third signal are input to the register,
wherein the first register comprises a seventh transistor, an eighth transistor, a ninth transistor, a tenth transistor, an eleventh transistor, a first inverter, and a second inverter,
wherein in the first register,
the first potential is input to one of a source and a drain of the seventh transistor,
the other of the source and the drain of the seventh transistor is electrically connected to one of a source and a drain of the eighth transistor,
the other of the source and the drain of the eighth transistor is electrically connected to one of a source and a drain of the ninth transistor,
the first signal is input to a gate of the eighth transistor,
the second signal is input to a gate of the ninth transistor,
the second potential is input to the other of the source and the drain of the ninth transistor,
an input terminal of the first inverter is electrically connected to an output terminal of the second inverter,
an input terminal of the second inverter is electrically connected to an output terminal of the first inverter,
a gate of the tenth transistor is electrically connected to the one of the source and the drain of the ninth transistor,
the first potential is input to one of a source and a drain of the tenth transistor,
the other of the source and the drain of the tenth transistor is electrically connected to one of a source and a drain of the eleventh transistor, and
the third signal is input to a gate of the eleventh transistor, and
wherein in the first register, a gate of the seventh transistor is electrically connected to the first input terminal, the input terminal of the first inverter is electrically connected to the first output terminal, and the other of the source and the drain of the eleventh transistor is electrically connected to the second output terminal.

22. The semiconductor device according to claim 20,
wherein each of the seventh to the eleventh transistors comprises an oxide semiconductor in a channel formation region.
